(19) United States
(12) Patent Application Publication
(10) Pub. No.: US 2026/0033317 A1
(43) Pub. Date: Jan. 29, 2026

(54) SEMICONDUCTOR PACKAGE STRUCTURES AND FABRICATION METHODS THEREOF

(71) Applicant: Yangtze Memory Technologies Holding Co., Ltd., Wuhan (CN)

(72) Inventors: Min Wen, Wuhan (CN); Liang Xiao, Wuhan (CN); Yi Zhao, Wuhan (CN); WenBin Zhou, Wuhan (CN); ZongLiang Huo, Wuhan (CN)

(21) Appl. No.: 19/274,238

(22) Filed: Jul. 18, 2025

(30) Foreign Application Priority Data
Jul. 23, 2024 (CN) 202410994338.7

(51) Int. Cl. H01L 23/528; H01L 23/00; H01L 25/065; H10B 12/00; H10B 80/00

(52) U.S. Cl. CPC H01L 23/528; H01L 23/5283; H01L 24/08; H01L 24/80; H01L 25/0657; H10B 80/00; H01L 2224/08145; H01L 2224/80895; H01L 2224/80896; H01L 2225/06524; H01L 2924/1436; H10B 12/033; H10B 12/09; H10B 12/31

(57) ABSTRACT

The present disclosure provides a semiconductor package structure and a fabrication method thereof. The semiconductor package structure includes: a plurality of first semiconductor chips arranged as being stacked along a first direction, wherein the first semiconductor chip includes at least one conductive structure; the conductive structure includes a first connection structure and a second connection structure both extending along the first direction, and an interconnection structure located between the first connection structure and the second connection structure in the first direction; and the interconnection structure is connected with both the first connection structure and the second connection structure; and a first hybrid bonding layer located between two adjacent ones of the first semiconductor chips in the first direction, wherein the first hybrid bonding layer includes at least one first bonding structure coupled with the conductive structures in the two adjacent ones of the first semiconductor chips.

### CROSS-REFERENCE TO RELATED APPLICATIONS

This application claims priority to and the benefit of Chinese Patent Application 202410994338.7, filed on Jul. 23, 2024, which is hereby incorporated by reference in its entirety.

### TECHNICAL FIELD

The present disclosure relates to the field of semiconductor technology, and particularly to a semiconductor package structures and a fabrication methods thereof.

### BACKGROUND

With the continuous development of the current science and technology, semiconductor devices are widely applied in various electronic apparatuses and electronic products. For example, the Dynamic Random Access Memory (DRAM), which is a volatile memory, is a semiconductor memory device commonly used in a computer.

### BRIEF DESCRIPTION OF THE DRAWINGS

FIG. 1 is a schematic diagram of an electronic apparatus provided by an example of the present disclosure;

FIG. 2 is a schematic diagram of a DRAM provided by an example of the present disclosure;

FIG. 3 is a schematic structural diagram I of a semiconductor package structure provided by an example of the present disclosure;

FIG. 4 is a schematic structural diagram of a part of a first hybrid bonding layer provided by an example of the present disclosure;

FIG. 5 is a schematic structural diagram of a conductive structure provided by an example of the present disclosure;

FIG. 6 is a schematic structural diagram I of a first semiconductor chip provided by an example of the present disclosure;

FIG. 7 is a schematic layout diagram of a first semiconductor chip provided by an example of the present disclosure;

FIG. 8 is a schematic enlarged view of a partial structure in FIG. 6;

FIG. 9 is a cross-sectional view of FIG. 8 along a line AA′;

FIG. 10 is a schematic structural diagram II of a semiconductor package structure provided by an example of the present disclosure;

FIG. 11 is a schematic structural diagram III of a semiconductor package structure provided by an example of the present disclosure;

FIG. 12 is a schematic structural diagram of a semiconductor package structure provided by another example of the present disclosure;

FIG. 13 is a schematic structural diagram of a first semiconductor chip provided by another example of the present disclosure;

FIG. 14 is a schematic flow diagram of a fabrication method of a semiconductor package structure provided by an example of the present disclosure;

FIGS. 15 to 24 are schematic structural diagrams of a fabrication process of a semiconductor package structure provided by an example of the present disclosure;

FIG. 25 is a schematic flow diagram of a fabrication method of a semiconductor package structure provided by another example of the present disclosure; and

FIGS. 26 to 29 are schematic structural diagrams of a fabrication process of a semiconductor package structure provided by another example of the present disclosure.

### DETAILED DESCRIPTION

Example implementations disclosed in the present disclosure will be described in more details below with reference to the drawings. Although the example implementations of the present disclosure are shown in the drawings, it is to be understood that the present disclosure may be implemented in various forms and should not be limited by the implementations set forth herein. Rather, these implementations are provided for a more thorough understanding of the present disclosure, and to fully convey a scope disclosed by the present disclosure to those skilled in the art.

In the following description, numerous details are given in order to provide a more thorough understanding of the present disclosure. However, it is apparent to those skilled in the art that the present disclosure may be implemented without one or more of these details. In other examples, in order to avoid confusing with the present disclosure, some technical features well-known in the art are not described; that is, not all features of actual examples are described here, and well-known functions and structures are not described in detail.

In the drawings, like reference numerals denote like elements throughout the specification.

It is to be understood that, spatially relative terms, such as “beneath”, “below”, “lower”, “under”, “over”, and “upper”, may be used herein for ease of description to describe the relationship between one element or feature and other elements or features as illustrated in the figures. It is to be understood that, the spatially relative terms are intended to further encompass different orientations of a device in use or operation in addition to the orientation depicted in the figures. For example, if a device in the figure is turned over, then an element or a feature described as being “below”, “under”, or “beneath” another element or feature will be orientated as being “above” another element or feature. Thus, the example terms, “below” and “beneath”, may comprise both upper and lower orientations. The device may be orientated otherwise (rotated by 90 degrees or in other orientations), and the spatially descriptive terms used herein are interpreted accordingly.

The terms used herein are only intended to describe the examples, and are not used as limitations of the present disclosure. As used herein, unless otherwise indicated expressly in the context, “a”, “an” and “the” in the singular form are also intended to comprise the plural form. It is also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

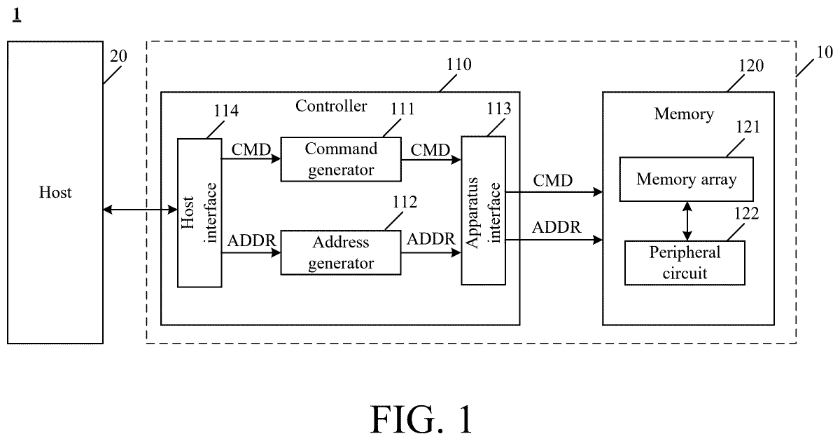

FIG. 1 is a schematic diagram of an electronic apparatus provided by an example of the present disclosure. The electronic apparatus 1 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having a memory therein.

As shown in FIG. 1, the electronic apparatus 1 may comprise a memory system 10 and a host 20, wherein the memory system 10 may comprise a memory 110 and a controller 120. The host 20 may comprise a processor of the electronic apparatus 1, for example, a central processing unit (CPU) or a system on chip (SoC) (such as an application processor (AP)). The controller 110 is coupled with both the host 20 and the memory 120, and the controller 110 may be configured to communicate with the host 20 and control the memory 120.

In some examples, the controller 110 may be configured to control operations of the memory 120, such as a read operation, an erase operation, and a write operation, and a refresh operation. In some implementations, the controller 110 is further configured to process an error correction code (ECC) with respect to data read from or written to the memory 120. In some other implementations, the controller 110 may be also configured to perform any other suitable operations, such as formatting the memory 120.

In some examples, the controller 110 may receive data, commands, and addresses from the host 20, and may send data, commands, and addresses to the memory 120. In an implementation, the controller 110 may comprise a command generator 111, an address generator 112, an apparatus interface 113, and a host interface 114. The controller 110 may receive the data, commands, and addresses from the host 20 through the host interface 114, decode the command received from the host 20 through the command generator 111 to generate an access command CMD, and provide the access command CMD to the memory 120 through the apparatus interface 113. The controller 110 may decode the address received from the host interface 114 through the address generator 112, to generate an address ADDR to be accessed in a memory array 121, and may provide the address ADDR to be accessed to the memory 120 through the apparatus interface 113. The access command may be a signal that instructs the memory 120 to write or read data by accessing one or more memory cells in the memory array 121 corresponding to the address ADDR. Furthermore, the controller 110 may also send a refresh command to the memory 120, wherein the refresh command may be a signal that instructs the memory 120 to read and rewrite data by accessing one or more memory cells in the memory array 121 corresponding to the address ADDR.

In some examples, the memory 120 may be a Random Access Memory (RAM), such as a Dynamic Random Access Memory (DRAM), a Synchronous Dynamic Random Access Memory (SDRAM), a Static Random Access Memory (SRAM), a Double Data Rate SDRAM (DDR SDRAM), a Phase-change Random Access Memory (PRAM), a Resistive Random Access Memory (ReRAM), or a Magnetic Random Access Memory (MRAM). The memory system 120 as being a DRAM is illustrated as an example below.

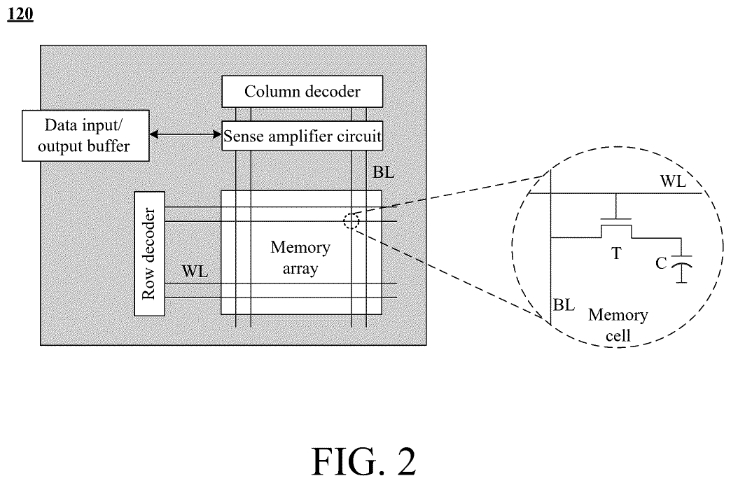

In some examples, FIG. 2 is a schematic diagram of a DRAM according to an example of the present disclosure. With combined reference to FIGS. 1 and 2, the DRAM comprises the memory array 121 and a peripheral circuit 122 coupled with the memory array 121, wherein the peripheral circuit 122 may comprise a sense amplifier circuit, a row decoder, a column decoder, and a data input/output buffer, etc. The memory array 121 comprises a plurality of memory cells arranged in an array, wherein a plurality of memory cells in a same row are coupled with a word line (WL), and a plurality of memory cells in a same column are coupled with a bit line (BL). Each memory cell comprises one transistor T and one capacitor C, wherein the word line WL is connected with a gate of the transistor T, the bit line BL is connected with one of a source and a drain of the transistor T, the other of the source and the drain of the transistor T is connected with one electrode of the capacitor C, and the other electrode of the capacitor C is connected with a fixed voltage. The memory cell is configured to store 1 or 0 using an amount of charge stored by the capacitor C. By designating a row address and a column address, each memory cell in a DRAM chip may be accessed independently, and a read operation, a write operation, or a refresh operation may be performed on data stored therein.

In some examples, in order to improve the integration level of DRAM, a package structure in which chips comprising DRAM memory arrays are arranged as being stacked along a vertical direction has been proposed, with vertically adjacent ones of the chips being connected by solder balls. However, the solder ball connection may increase the thickness of the entire package structure, and a reduction of a spacing between adjacent chips may affect the reliability of the solder ball connection.

In this regard, the present disclosure provides the following implementations.

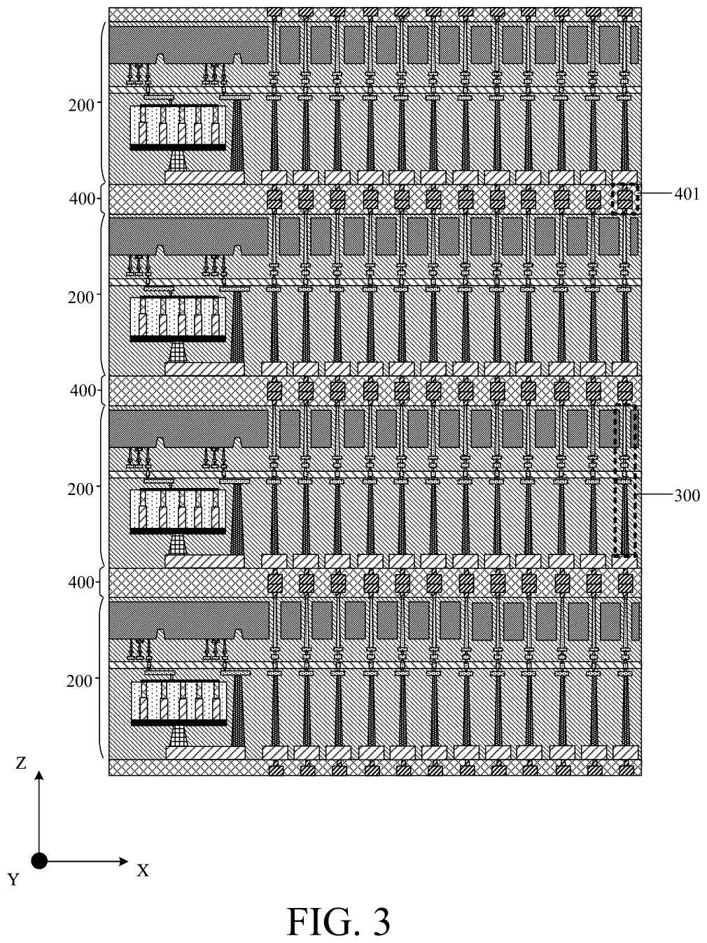

The present disclosure provides a semiconductor package structure. FIG. 3 is a schematic structural diagram of the semiconductor package structure provided by an example of the present disclosure. As shown in FIG. 3, the semiconductor package structure comprises: a plurality of first semiconductor chips 200 arranged as being stacked along a first direction, and a first hybrid bonding layer 400 located between two adjacent ones of the first semiconductor chips 200 in the first direction, wherein the first semiconductor chip 200 comprises at least one conductive structure 300, the first hybrid bonding layer 400 comprises at least one first bonding structure 401, and the first bonding structure 401 is coupled with conductive structures 300 in the two adjacent ones of the first semiconductor chips 200. Here, the first direction may be a Z direction. It is to be noted that both the number of the first semiconductor chips 200 and the number of the conductive structures 300 in each first semiconductor chip 200 in the figure are examples only, and the present disclosure impose no limitations on the number of the first semiconductor chips 200 and the number of the conductive structures 300 in each first semiconductor chip 200.

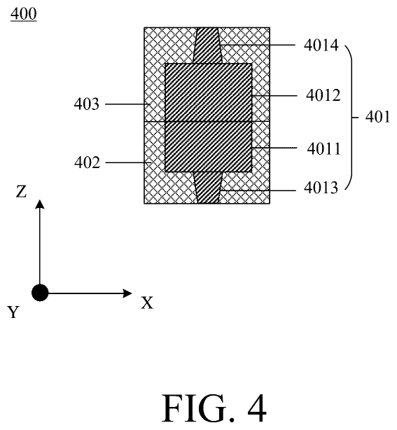

In some examples, FIG. 4 is a schematic structural diagram of a part of the first hybrid bonding layer 400. As shown in FIG. 4, the first hybrid bonding layer 400 comprises a first dielectric layer 402 and a second dielectric layer 403 arranged as being stacked along the first direction, and the first bonding structure 401. The first bonding structure 401 comprises a first bonding pad 4011 and a second bonding pad 4012 arranged as being stacked along the first direction, wherein the first bonding pad 4011 is located in the first dielectric layer 402, the second bonding pad 4012 is located in the second dielectric layer 403, the first bonding pad 4011 is in contact and bonded with the second bonding pad 4012, and the first dielectric layer 402 is in contact and bonded with the second dielectric layer 403.

In some examples, both the first bonding pad 4011 and the second bonding pad 4012 comprise a conductive material, such as at least one of a doped semiconductor material (such as doped silicon, doped germanium, or the like), a conductive metal nitride (such as titanium nitride, tantalum nitride, or the like), a metal material (such as aluminum, copper, tungsten, titanium, tantalum, or the like), and a metal semiconductor compound (such as tungsten silicide, cobalt silicide, titanium silicide, or the like). Both the first dielectric layer 402 and the second dielectric layer 403 comprise a dielectric material, such as silicon oxide, silicon nitride, silicon oxynitride, insulating polymer, or any combination thereof.

In an example, the first bonding pad 4011 and the second bonding pad 4012 may comprise the same material. For example, both the first bonding pad 4011 and the second bonding pad 4012 may comprise copper, and copper-copper bonding may be formed between the first bonding pad 4011 and the second bonding pad 4012, so that there may be no distinct boundary between the first bonding pad 4011 and the second bonding pad 4012. The first dielectric layer 402 and the second dielectric layer 403 may also comprise the same material. For example, both the first dielectric layer 402 and the second dielectric layer 403 may comprise silicon oxide, and silicon oxide-silicon oxide bonding may be formed between the first dielectric layer 402 and the second dielectric layer 403, so that there may be no distinct boundary between the first dielectric layer 402 and the second dielectric layer 403.

In some examples, with continued reference to FIG. 4, the first bonding structure 401 may further comprise a first conductive pillar 4013 located in the first dielectric layer 402 and a second conductive pillar 4014 located in the second dielectric layer 403, wherein the size of the first conductive pillar 4013 in an X direction may be less than the size of the first bonding pad 4011 in the X direction, and the size of the second conductive pillar 4014 in the X direction may be less than the size of the second bonding pad 4012 in the X direction. In some examples, the first conductive pillar 4013 and the first bonding pad 4011 may be formed integrally, and the second conductive pillar 4014 and the second bonding pad 4012 may be formed integrally, that is, there may be no boundary between the first conductive pillar 4013 and the first bonding pad 4011, and there may be no boundary between the second conductive pillar 4014 and the second bonding pad 4012.

In the example of the present disclosure, two adjacent ones of the first semiconductor chips 200 are connected through the first hybrid bonding layer 400. Hybrid bonding is direct bonding, and compared with that in a chip stacking structure formed by solder ball bonding, a spacing between the first bonding structures 401 may be smaller, thereby facilitating high broadband connection between the chips. In addition, since no space is required to be reserved for a bottom filling material that fills between the bonding structures, the size of the first hybrid bonding layer 400 in the stacking direction of the chips may be smaller, thereby facilitating the reduction of the thickness of the semiconductor package structure.

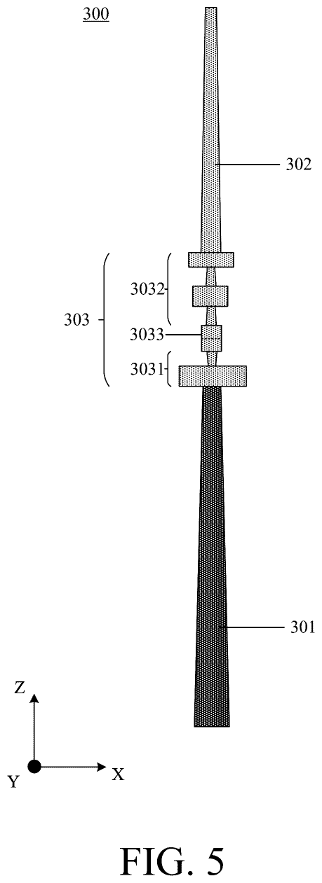

In some examples, FIG. 5 is a schematic structural diagram of the conductive structure provided by an example of the present disclosure. As shown in FIG. 5, the conductive structure 300 comprises a first connection structure 301 extending along the first direction, a second connection structure 302 extending along the first direction, and an interconnection structure 303 located between the first connection structure 301 and the second connection structure 302 in the first direction. The interconnection structure 303 comprises a first interconnection sub-structure 3031, a second bonding structure 3033, and a second interconnection sub-structure 3032 arranged as being stacked along the first direction, the first interconnection sub-structure 3031 is located between the first connection structure 301 and the second bonding structure 3033, and the second interconnection sub-structure 3032 is located between the second connection structure 302 and the second bonding structure 3033.

Here, both the first interconnection sub-structure 3031 and the second interconnection sub-structure 3032 may comprise a plurality of conductive layers and conductive pillars connected with the conductive layers, and the numbers of conductive layers and conductive pillars shown in the figure are illustrative only.

In some examples, with continued reference to FIG. 5, in a second direction, the size of an end in two opposite ends of the first connection structure 301 along the first direction close to the second connection structure 302 is less than the size of an end away from the second connection structure 302; in the second direction, the size of an end in two opposite ends of the second connection structure 302 along the first direction close to the first connection structure 301 is greater than the size of an end away from the first connection structure 301; and the second direction is perpendicular to the first direction. Here, the second direction may be the X direction.

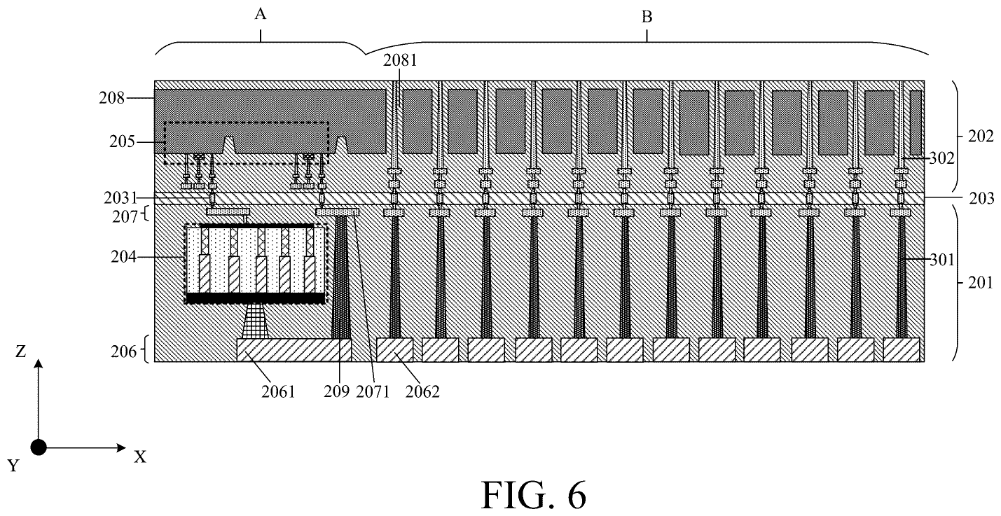

In some examples, FIG. 6 is a schematic structural diagram of the first semiconductor chip. With combined reference to FIGS. 5 and 6, the first semiconductor chip 200 comprises: a first semiconductor structure 201, a bonding layer 203, and a second semiconductor structure 202 arranged as being stacked along the first direction, wherein the first semiconductor structure 201 comprises the first connection structure 301, the first interconnection sub-structure 3031, and a memory array 204; the second semiconductor structure 202 comprises the second connection structure 302, the second interconnection sub-structure 3032, and a peripheral circuit 205; the bonding layer 203 comprises the second bonding structure 3033 and a third bonding structure 2031; and the memory array 204 is coupled with the peripheral circuit 205 through the third bonding structure 2031.

In some examples, the bonding layer 203 may be a hybrid bonding layer, and both the second bonding structure 3033 and the third bonding structure 2031 may be metal-metal bonding structures.

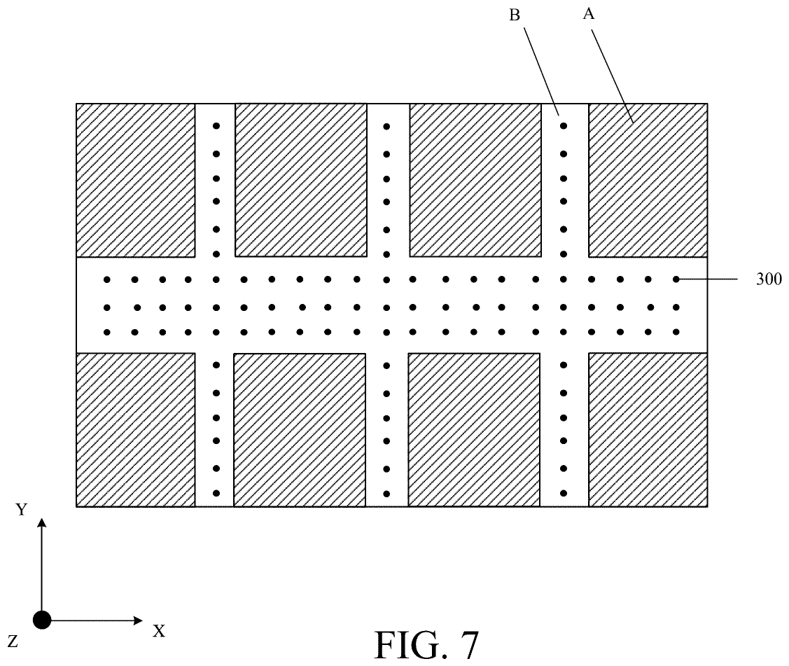

FIG. 7 is a schematic layout diagram of the first semiconductor chip provided by an example of the present disclosure. With combined reference to FIGS. 6 and 7, the first semiconductor chip 200 comprises a memory region A and a contact region B arranged in juxtaposition along a direction perpendicular to the first direction, and the conductive structure 300 is located in the contact region B. The memory array 204 and the peripheral circuit 205 are located in the memory region B. It is to be noted that a layout pattern of the memory region A and the contact region B in FIG. 7 is an example only.

In the example of the present disclosure, the first semiconductor structure 201 and the second semiconductor structure 202 in the first semiconductor chip 200 may also be connected through the hybrid bonding layer, whereby the memory array 204 and the peripheral circuit 205 may be arranged along the stacking direction of the chips. On the one hand, the length of a connection line between the memory array 204 and the peripheral circuit 205 may be reduced, improving the reliability of signal transmission. On the other hand, the area of the memory region A may be reduced, facilitating the miniaturization of the semiconductor package structure.

In some examples, with continued reference to FIG. 6, the second semiconductor structure 202 comprises: a semiconductor layer 208 extending along the direction perpendicular to the first direction, wherein a partial structure of the peripheral circuit 205 is located in the semiconductor layer 208 in the memory region A; and the second connection structure 302 penetrates through the semiconductor layer 208 located in the contact region B along the first direction. The second semiconductor structure 202 further comprises an isolation layer 2081 located between the second connection structure 302 and the semiconductor layer 208, wherein the isolation layer 2081 surrounds the second connection structure 302, so that the second connection structure 302 is isolated from the semiconductor layer 208, and an end of the second connection structure 302 may be exposed from the isolation layer 2081.

In some examples, the semiconductor layer 208 may comprise at least one of semiconductor materials such as silicon, germanium, and silicon germanide, and the peripheral circuit 205 may comprise a plurality of CMOS transistors, wherein an active region of the CMOS transistor may be located in the semiconductor layer 208, and a gate structure of the CMOS transistor is located on a side surface of the semiconductor layer 208.

In some examples, the first semiconductor structure 201 further comprises: a first pad-out layer 206 located on a side in two opposite sides of the memory array 204 along the first direction away from the peripheral circuit 205 and located on a side in two opposite sides of the first connection structure 301 along the first direction away from the second connection structure 302; the first pad-out layer 206 comprises a first interconnection line 2061 and first leading-out pads 2062. With combined reference to FIGS. 3 and 6, two opposite ends of one of the first leading-out pads 2062 along the first direction are connected with one first connection structure 301 and one first bonding structure 401, respectively. Furthermore, the first interconnection line 2061 is coupled with both the memory array 204 and the peripheral circuit 205. The first pad-out layer 206 may further comprise a second interconnection line (not shown in the figure) coupled with the peripheral circuit 205 or the memory array 204, and the second interconnection line may be coupled with the first leading-out pad 2062, so as to implement leading-out of memory devices comprising the memory array 204 and the peripheral circuit 205.

In some examples, all the first connection structure 301, the second connection structure 302, the interconnection structure 303, and the first leading-out pad 2062 comprise a conductive material. Here, the conductive material may be one of a doped semiconductor material (such as doped silicon, doped germanium, or the like), a conductive metal nitride (such as titanium nitride, tantalum nitride, or the like), a metal material (such as aluminum, copper, tungsten, titanium, tantalum, or the like), and a metal semiconductor compound (such as tungsten silicide, cobalt silicide, titanium silicide, or the like).

In some examples, a material of the first connection structure 301 may be different from a material of the second connection structure 302, and a material of the first leading-out pad 2062 may be different from the material of the first connection structure 301.

In some examples, the material of the first connection structure 301 comprises tungsten, materials of the second connection structure 302 and the interconnection structure 303 both comprise copper, and the material of the first leading-out pad 2062 comprises aluminum.

In some examples, with continued reference to FIG. 6, the first semiconductor structure 201 further comprises: a routing layer 207 located between the bonding layer 203 and the memory array 204 and between the bonding layer 203 and the first connection structure 301. With combined reference to FIGS. 5 and 6, the routing layer 207 comprises the first interconnection sub-structure 3031 and a first routing 2071, wherein the first routing 2071 is located between the memory array 204 and the peripheral circuit 205. The first semiconductor structure 201 further comprises a third connection structure 209 extending along the first direction, wherein two opposite ends of the third connection structure 209 along the first direction are connected with the first routing 2071 and the first interconnection line 2061, respectively.

In some examples, the size of the third connection structure 209 in the first direction is equal to the size of the first connection structure 301 in the first direction. It is to be noted that the size of the third connection structure 209 in the first direction being equal to the size of the first connection structure 301 in the first direction means that the sizes of them are substantially equal within an allowed process error range.

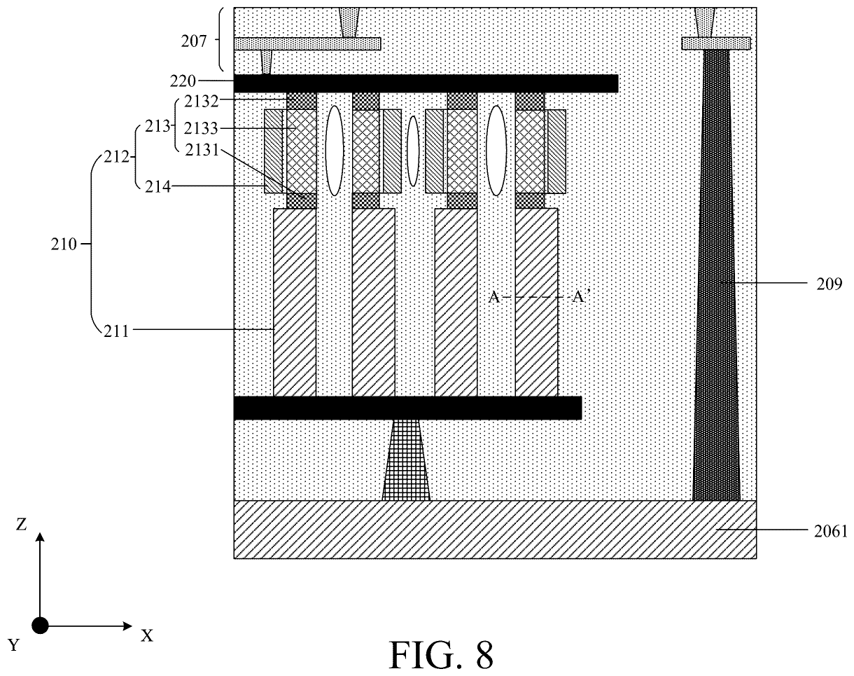

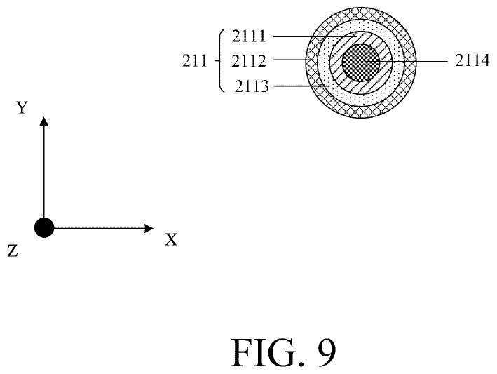

In some examples, FIG. 8 is a schematic enlarged view of a partial structure in FIG. 6, and FIG. 9 is a cross-sectional view of FIG. 8 along a line AA′. With combined reference to FIGS. 6, 8, and 9, the memory array 204 comprises: a plurality of memory cells 210, wherein the memory cell 210 comprises a capacitor structure 211 and a transistor structure 212 arranged as being stacked along the first direction; the capacitor structure 211 comprises a first plate 2111, a second plate 2112, a dielectric layer 2113 located between the first plate 2111 and the second plate 2112, and a support structure 2114; the transistor structure 212 comprises a semiconductor body 213 extending along the first direction, an end in two opposite ends of the semiconductor body 213 along the first direction is connected with the first plate 2111 of the capacitor structure 211, and the second plate 2112 of the capacitor structure 211 is coupled with the first interconnection line 2061.

It is to be noted that the structure of the capacitor structure 211 shown in FIGS. 8 and 9 is an example only. In some examples, the capacitor structure may not comprise the support structure, and may comprise only the first plate, the second plate, and the dielectric layer located between the first plate and the second plate. In some other examples, the capacitor structure may also have any other suitable structure, and the present disclosure imposes no limitations thereto.

In some examples, with reference to FIG. 8, the semiconductor body 213 comprises a first electrode structure 2131, a channel structure 2133, and a second electrode structure 2132 arranged sequentially along the first direction. The transistor structure 212 further comprises: a gate structure 214 and a gate dielectric layer 215, wherein the gate structure 214 is located on at least one side of the channel structure 2133 along a direction perpendicular to the first direction, and the gate dielectric layer 215 is located between the gate structure 214 and the channel structure 2133; the gate structures 214 of a plurality of transistor structures 212 arranged along a third direction are connected to constitute a word line structure extending along the third direction, the second electrode structures 2132 of a plurality of transistor structures 212 arranged along the second direction may be connected with a bit line structure 220 extending along the second direction, and the bit line structure 220 may be further connected with the routing layer 207. Here, both the second direction and the third direction are perpendicular to the first direction, the second direction may be the X direction, and the third direction may be a Y direction.

In some examples, the gate structure 214 comprises a conductive material, such as at least one of a doped semiconductor material (such as doped silicon, doped germanium, or the like), a conductive metal nitride (such as titanium nitride, tantalum nitride, or the like), a metal material (such as aluminum, copper, tungsten, titanium, tantalum, or the like), and a metal semiconductor compound (such as tungsten silicide, cobalt silicide, titanium silicide, or the like). The gate dielectric layer 215 may comprise at least one of a high dielectric constant material, silicon oxide, silicon nitride, and silicon oxynitride, wherein the high dielectric constant material may comprise at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

It is to be noted that the disposing pattern of the gate structure 214 in FIG. 8 is an example only. In some other examples, the gate structure may be located on two sides or three sides of the channel structure or around the channel structure, and the present disclosure imposes no limitations thereto.

In the examples of the present disclosure, the memory cell 210 in the memory array 204 is composed of the transistor structure 212 and the capacitor structure 211, wherein the transistor structure 212 is a vertical transistor comprising the semiconductor body 213 extending along the first direction, facilitating a further reduction of the area of the memory region A and an increase of a storage density. Furthermore, an extension direction of the memory cell 210, the stacking direction of the chips, the stacking direction of the memory array 204 and the peripheral circuit 205, and an extension direction of the conductive structure 300 are the same, facilitating three-dimensional integration of the semiconductor package structure.

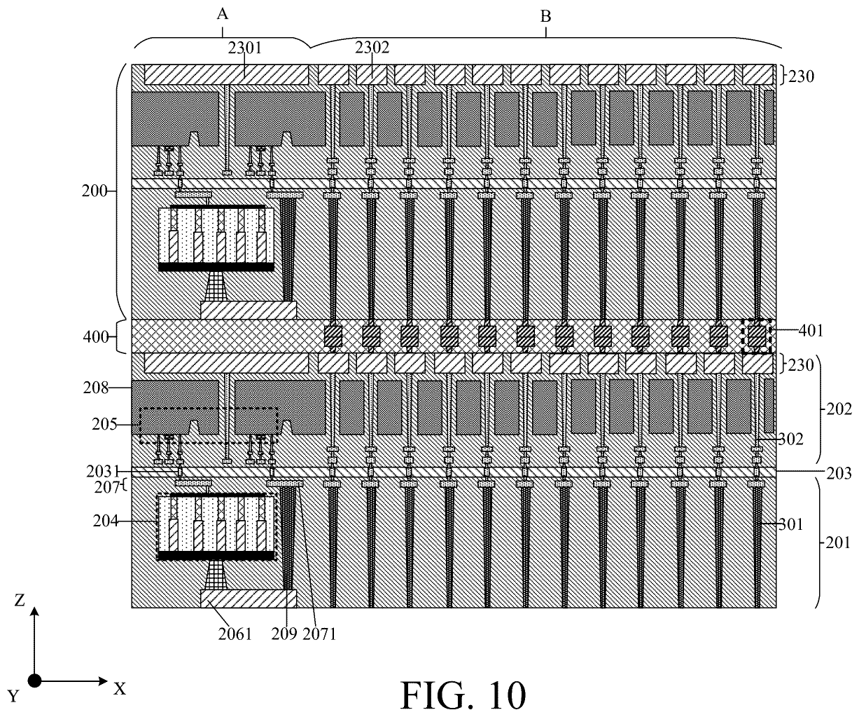

In the above examples, the pad-out layer as being disposed on a side of the memory array away from the peripheral circuit is used as an example, and in some other examples, the pad-out layer may also be disposed on a side of the peripheral circuit away from the memory array. FIG. 10 is a schematic structural diagram of two adjacent ones of the first semiconductor chips. As shown in FIG. 10, the second semiconductor structure 202 comprises: a second pad-out layer 230 located on a side in two opposite sides of the peripheral circuit 205 along the first direction away from the memory array 204 and located on a side in two opposite sides of the second connection structure 302 along the first direction away from the first connection structure 301, wherein the second pad-out layer 230 comprises a second interconnection line 2301 and second leading-out pads 2302, two opposite ends of one of the second leading-out pads 2302 along the first direction are connected with one second connection structure 302 and one first bonding structure 401, respectively.

In some examples, when the memory device comprising the memory array 204 and the peripheral circuitry 205 are led out from a side of the peripheral circuit 205, in the second direction, the size of the end in the two opposite ends of the first connection structure 301 along the first direction close to the second connection structure 302 may be greater than the size of the end away from the second connection structure 302; and in the second direction, the size of the end in the two opposite ends of the second connection structure 302 along the first direction close to the first connection structure 301 may be less than the size of the end away from the first connection structure 301.

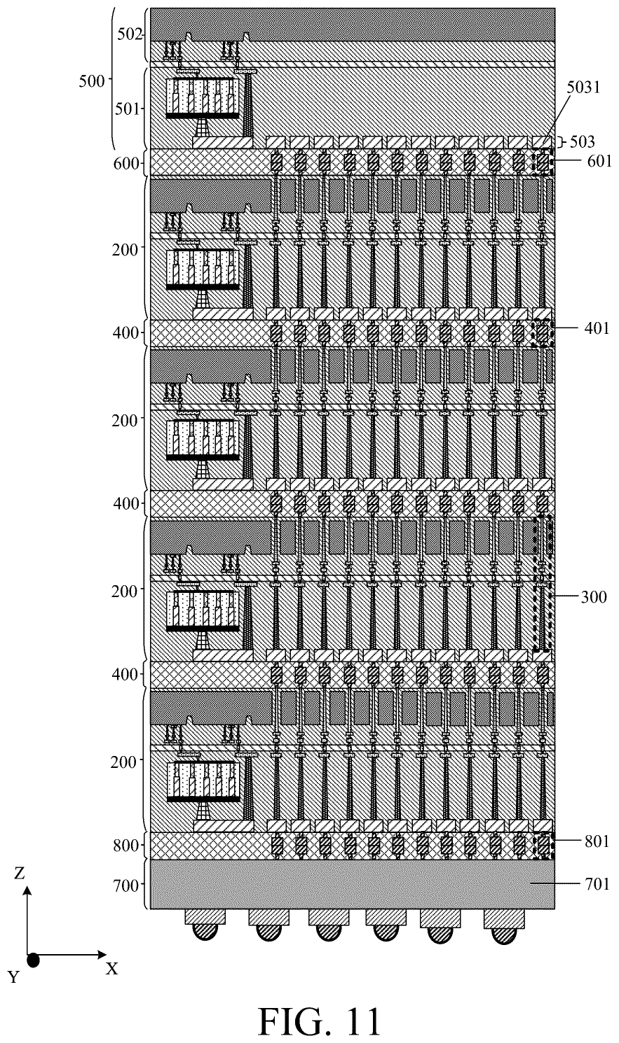

In some examples, the plurality of first semiconductor chips may be further integrated with a second semiconductor chip and a third semiconductor chip. FIG. 11 is a schematic structural diagram of the semiconductor package structure comprising a plurality of first semiconductor chips, one second semiconductor chip, and one third semiconductor chip provided by examples of the present disclosure.

As shown in FIG. 11, the semiconductor package structure further comprises: a second semiconductor chip 500 arranged as being stacked with the plurality of first semiconductor chips 200 along the first direction, wherein the second semiconductor chip 500 comprises a third semiconductor structure 501 and a fourth semiconductor structure 502 arranged as being stacked along the first direction; the third semiconductor structure 501 is located between the fourth semiconductor structure 502 and the first semiconductor chip 200; the third semiconductor structure 501 comprises a third pad-out layer 503 on a side in two opposite sides along the first direction away from the fourth semiconductor structure 502; and the third pad-out layer 503 comprises at least one third leading-out pad 5031.

Here, the second semiconductor chip 500 may be a memory chip located at a topmost layer in the package structure, and the second semiconductor chip 500 is distinguished from the first semiconductor chip 200 in that a conductive structure that penetrates through the second conductor chip 500 along the first direction and that is used for connecting the second semiconductor chip 500 with other semiconductor chips may not be provided in the second semiconductor chip 500.

In some examples, the semiconductor package structure further comprises: a second hybrid bonding layer 600 located between the first semiconductor chip 200 closest to the second semiconductor chip 500 and the second semiconductor chip 500, wherein the second hybrid bonding layer 600 comprises at least one fourth bonding structure 601; and the fourth bonding structure 601 is coupled with the third leading-out pad 5031 and coupled with the conductive structure 300 of the first semiconductor chip 200 closest to the second semiconductor chip 500.

In some examples, with continued reference to FIG. 11, the semiconductor package structure further comprises: a third semiconductor chip 700 arranged as being stacked with the plurality of first semiconductor chips 200 along the first direction, wherein the third semiconductor chip 700 comprises a control circuit 701; and the plurality of first semiconductor chips 200 are located between the second semiconductor chip 500 and the third semiconductor chip 700.

In some examples, the semiconductor package structure further comprises: a third hybrid bonding layer 800 located between the third semiconductor chip 700 and the first semiconductor chip 200 closest to the third semiconductor chip 700 in the first direction, wherein the third hybrid bonding layer 800 comprises at least one fifth bonding structure 801; and the fifth bonding structure 801 is coupled with the conductive structure 300 and the control circuit 701.

In the examples of the present disclosure, all the plurality of semiconductor chips arranged as being stacked along the first direction may be connected through the hybrid bonding layer, and the bonding structure in the hybrid bonding layer may be connected with the conductive structure 300 extending along the first direction in the first semiconductor chip 200 and the first leading-out pad 2062, whereby a plurality of memory chips may be all coupled to the third semiconductor chip 700.

In some examples, the third semiconductor chip 700 may further comprise an external connection structure on a side in two opposite sides along the first direction away from the first semiconductor chip 200, and the external connection structure may be configured to connect the semiconductor package structure with an interposer or a package substrate.

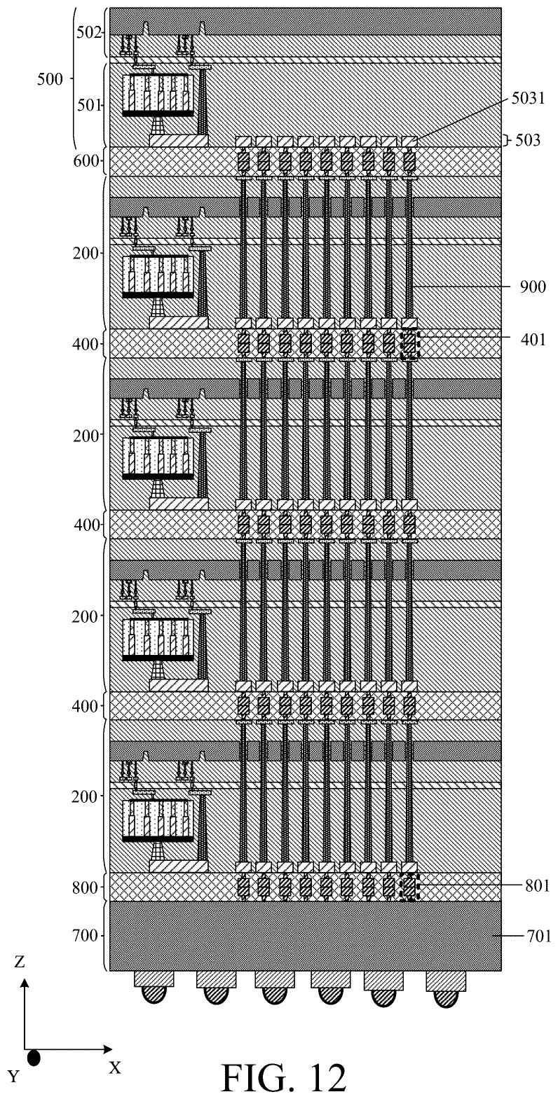

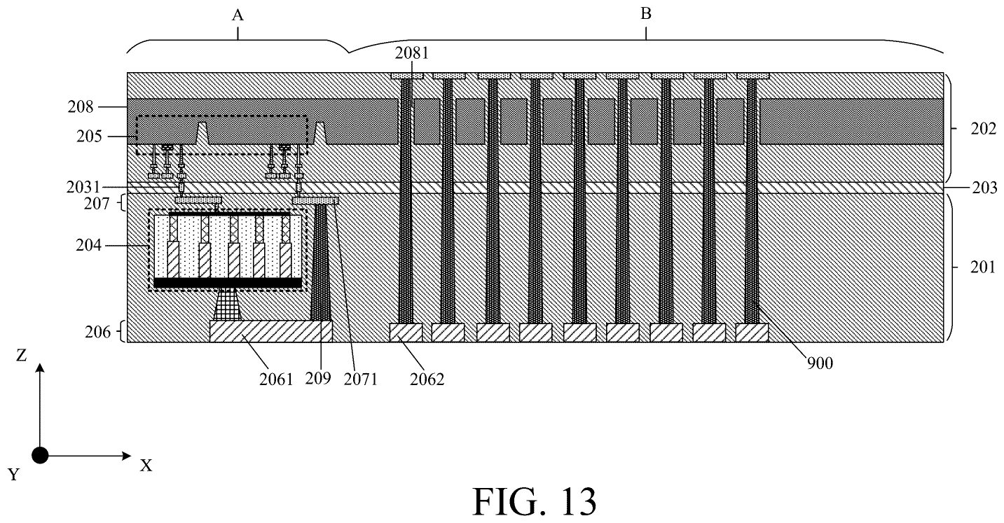

Based on an idea similar to that of the semiconductor package structure mentioned above, examples of the present disclosure further provide a semiconductor package structure. FIG. 12 is a schematic structural diagram of the semiconductor package structure. FIG. 13 is a schematic structural diagram of a first semiconductor chip in the semiconductor package structure. With combined reference to FIGS. 12 and 13, the semiconductor package structure comprises a plurality of first semiconductor chips 200 arranged as being stacked along a first direction and a first hybrid bonding layer 400 located between two adjacent ones of the first semiconductor chips 200 in the first direction, wherein the first semiconductor chip 200 comprises a first semiconductor structure 201, a bonding layer 203, and a second semiconductor structure 202 arranged as being stacked along the first direction, and at least one connection structure 900; the connection structure 900 penetrates through the bonding layer 203 along the first direction and extends into the first semiconductor structure 201 and the second semiconductor structure 202; the first hybrid bonding layer 400 comprises at least one first bonding structure 401; and the first bonding structure 401 is coupled with the connection structures 900 in the two adjacent ones of the first semiconductor chips 200.

In some examples, with combined reference to FIGS. 4 and 12, the first hybrid bonding layer 400 comprises a first dielectric layer 402 and a second dielectric layer 403 arranged as being stacked along the first direction, and the first bonding structure 401. The first bonding structure 401 comprises a first bonding pad 4011 and a second bonding pad 4012 arranged as being stacked along the first direction, wherein the first bonding pad 4011 is disposed in the first dielectric layer 402, the second bonding pad 4012 is located in the second dielectric layer 403, the first bonding pad 4011 is in contact and bonded with the second bonding pad 4012, and the first dielectric layer 402 is in contact and bonded with the second dielectric layer 403.

In some examples, both the first bonding pad 4011 and the second bonding pad 4012 comprise a conductive material, such as at least one of a doped semiconductor material (such as doped silicon, doped germanium, or the like), a conductive metal nitride (such as titanium nitride, tantalum nitride, or the like), a metal material (such as aluminum, copper, tungsten, titanium, tantalum, or the like), and a metal semiconductor compound (such as tungsten silicide, cobalt silicide, titanium silicide, or the like). Both the first dielectric layer 402 and the second dielectric layer 403 comprise a dielectric material, such as silicon oxide, silicon nitride, silicon oxynitride, insulating polymers, or any combination thereof.

In an example, the first bonding pad 4011 and the second bonding pad 4012 may comprise the same material. For example, both the first bonding pad 4011 and the second bonding pad 4012 may comprise copper, and copper-copper bonding may be formed between the first bonding pad 4011 and the second bonding pad 4012, so that there may be no distinct boundary between the first bonding pad 4011 and the second bonding pad 4012. The first dielectric layer 402 and the second dielectric layer 403 may also comprise the same material. For example, both the first dielectric layer 402 and the second dielectric layer 403 may comprise silicon oxide, and silicon oxide-silicon oxide bonding may be formed between the first dielectric layer 402 and the second dielectric layer 403, so that there may be no distinct boundary between the first dielectric layer 402 and the second dielectric layer 403.

In some examples, with continued reference to FIG. 4, the first bonding structure 401 may further comprise a first conductive pillar 4013 located in the first dielectric layer 402 and a second conductive pillar 4014 located in the second dielectric layer 403, wherein the size of the first conductive pillar 4013 in an X direction may be less than the size of the first bonding pad 4011 in the X direction, and the size of the second conductive pillar 4014 in the X direction may be less than the size of the second bonding pad 4012 in the X direction. In some examples, the first conductive pillar 4013 and the first bonding pad 4011 may be formed integrally, and the second conductive pillar 4014 and the second bonding pad 4012 may be formed integrally, that is, there may be no boundary between the first conductive pillar 4013 and the first bonding pad 4011, and there may be no boundary between the second conductive pillar 4014 and the second bonding pad 4012.

In some examples, with reference to FIG. 13, the first semiconductor chip 200 comprises: a memory region A and a contact region B arranged in juxtaposition along a direction perpendicular to the first direction, wherein the connection structure 900 is located in the contact region B; the memory region A comprises a memory array 204 and a peripheral circuit 205 arranged as being stacked along the first direction, and at least one third bonding structure 2031 located between the memory array 204 and the peripheral circuit 205; and the third bonding structure 2031 is coupled with both the memory array 204 and the peripheral circuit 205. The memory array 204 is located in the first semiconductor structure 201, the peripheral circuit 205 is located in the second semiconductor structure 202, and the third bonding structure 2031 is located in the bonding layer 203.

In some examples, the second semiconductor structure 202 comprises: a semiconductor layer 208 extending along the direction perpendicular to the first direction, wherein a partial structure of the peripheral circuit 205 is located in the semiconductor layer 208 in the memory region A; and the connection structure 900 penetrates through the semiconductor layer 208 located in the contact region B along the first direction.

In some examples, the second semiconductor structure 202 further comprises: an isolation layer 2081 located between the connection structure 900 and the semiconductor layer 208.

In some examples, the first semiconductor structure 201 further comprises: a first pad-out layer 206 located on a side in two opposite sides of the memory array 204 along the first direction away from the peripheral circuit 205 and extending into the contact region B along the direction perpendicular to the first direction, wherein the first pad-out layer 206 comprises a first interconnection line 2061 and first leading-out pads 2062; two opposite ends of one of the first leading-out pads 2062 along the first direction are connected with one connection structure 900 and one first bonding structure 401, respectively; and the first interconnection line 2061 is coupled with both the memory array 204 and the peripheral circuit 205.

In some examples, both the first leading-out pad 2062 and the connection structure 900 comprise a conductive material. Here, the conductive material may be one of a doped semiconductor material (such as doped silicon, doped germanium, or the like), a conductive metal nitride (such as titanium nitride, tantalum nitride, or the like), a metal material (such as aluminum, copper, tungsten, titanium, tantalum, or the like), and a metal semiconductor compound (such as tungsten silicide, cobalt silicide, titanium silicide, or the like).

In an example, a material of the first leading-out pad 2062 comprises aluminum, and a material of the connection structure 900 comprises copper.

In an example, with reference to FIG. 13, in the second direction, the size of an end in two opposite ends of the connection structure 900 along the first direction located in the first semiconductor structure 201 is greater than the size of an end located in the second semiconductor structure 202. Here, the second direction is the X direction.

In some examples, with combined reference to FIGS. 8, 9, and 13, the memory array 204 comprise: a plurality of memory cells 210, wherein the memory cell 210 comprises a capacitor structure 211 and a transistor structure 212 arranged as being stacked along the first direction; the capacitor structure 211 comprises a first plate 2111, a second plate 2112, and a dielectric layer 2113 located between the first plate 2111 and the second plate 2112; the transistor structure 212 comprises a semiconductor body 213 extending along the first direction; an end in two opposite ends of the semiconductor body 213 along the first direction is connected with the first plate 2111 of the capacitor structure 211; and the second plate 2112 of the capacitor structure 211 is coupled with the first interconnection line 2061.

In some examples, the semiconductor body 213 comprises a first electrode structure 2131, a channel structure 2133, and a second electrode structure 2132. The transistor structure 212 further comprises: a gate structure 214 and a gate dielectric layer 215, wherein the gate structure 214 is located on at least one side of the channel structure 2133 along a direction perpendicular to the first direction, and the gate dielectric layer 215 is located between the gate structure 214 and the channel structure 2133; the gate structures 214 of a plurality of transistor structures 212 arranged along a third direction are connected to constitute a word line structure extending along the third direction, the second electrode structures 2132 of a plurality of transistor structures 212 arranged along the second direction may be connected with a bit line structure 220 extending along the second direction, and the bit line structure 220 may be further connected with the routing layer 207. Here, both the second direction and the third direction are perpendicular to the first direction, the second direction may be the X direction, and the third direction may be a Y direction.

In some examples, the gate structure 214 comprises a conductive material, such as at least one of a doped semiconductor material (such as doped silicon, doped germanium, or the like), a conductive metal nitride (such as titanium nitride, tantalum nitride, or the like), a metal material (such as aluminum, copper, tungsten, titanium, tantalum, or the like), and a metal semiconductor compound (such as tungsten silicide, cobalt silicide, titanium silicide, or the like). The gate dielectric layer 215 may comprise at least one of a high dielectric constant material, silicon oxide, silicon nitride, and silicon oxynitride, wherein the high dielectric constant material may comprise at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some examples, with reference to FIG. 12, the semiconductor package structure further comprises: a second semiconductor chip 500 arranged as being stacked with the plurality of first semiconductor chips 200 along the first direction, wherein the second semiconductor chip comprises a third semiconductor structure 501 and a fourth semiconductor structure 502 arranged as being stacked along the first direction; the third semiconductor structure 501 is located between the fourth semiconductor structure 502 and the first semiconductor chip 200; the third semiconductor structure 501 comprises a third pad-out layer 503 on a side in two opposite sides along the first direction away from the fourth semiconductor structure 502; and the third pad-out layer 503 comprises at least one third leading-out pad 5031.

In some examples, the semiconductor package structure further comprises: a second hybrid bonding layer 600 located between the first semiconductor chip 200 closest to the second semiconductor chip 500 and the second semiconductor chip 500, wherein the second hybrid bonding layer 600 comprises at least one fourth bonding structure 601; and the fourth bonding structure 601 is coupled with the third leading-out pad 5031 and coupled with the connection structure 900 of the first semiconductor chip 200 closest to the second semiconductor chip 500. Here, the second semiconductor chip 500 may be a memory chip located at a topmost layer in the package structure, and the second semiconductor chip 500 is distinguished from the first semiconductor chip 200 in that a connection structure that penetrates through the second conductor chip 500 along the first direction and that is used for connecting the second semiconductor chip 500 with other semiconductor chips may not be provided in the second semiconductor chip 500.

In some examples, with continued reference to FIG. 12, the semiconductor package structure further comprises: a third semiconductor chip 700 arranged as being stacked with the plurality of first semiconductor chips 200 along the first direction, wherein the third semiconductor chip 700 comprises a control circuit 701; and the plurality of first semiconductor chips 200 are located between the second semiconductor chip 500 and the third semiconductor chip 700.

In some examples, the semiconductor package structure further comprises: a third hybrid bonding layer 800 located between the third semiconductor chip 700 and the first semiconductor chip 200 closest to the third semiconductor chip 700 in the first direction, wherein the third hybrid bonding layer 800 comprises at least one fifth bonding structure 801; and the fifth bonding structure 801 is coupled with the connection structure 900 and the control circuit 701.

In the examples of the present disclosure, the plurality of first semiconductor chips 200 are arranged as being stacked along the first direction, the first semiconductor chip 200 comprises the conductive structure 300 or the connection structure 900 extending along the first direction, two adjacent ones of the first semiconductor chips 200 are connected through the first hybrid bonding layer 400, and the first hybrid bonding layer 400 comprises the first bonding structure 401 coupled with the conductive structure 300 or the connection structure 900. Compared with a bonding structure between semiconductor chips connected by solder balls, there may be a smaller spacing between first bonding structures 401 in the first hybrid bonding layer 400, and since no space is required to be reserved for a bottom filling material, there may also be a smaller spacing between two adjacent ones of the first semiconductor chips 200. On the one hand, more first bonding structures 401 can be provided in the same area, thereby facilitating high broadband connection between the chips. On the other hand, the thickness of the semiconductor package structure may be reduced, facilitating the miniaturization of the semiconductor package structure.

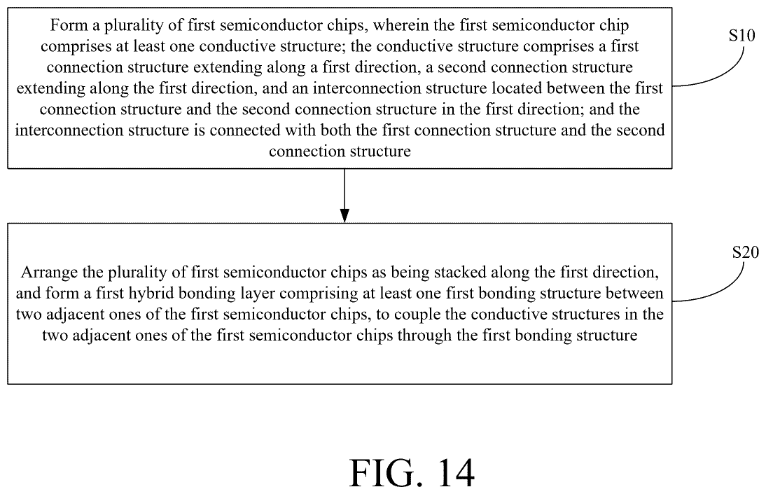

Based on an idea similar to that of the semiconductor package structure mentioned above, the present disclosure further provides a fabrication method of a semiconductor package structure. FIG. 14 is a schematic flow diagram of a fabrication method of a semiconductor package structure provided by examples of the present disclosure. The fabrication method of a semiconductor package structure comprises the following operations:

Operation S10: forming a plurality of first semiconductor chips, wherein the first semiconductor chip comprises at least one conductive structure; the conductive structure comprises a first connection structure extending along a first direction, a second connection structure extending along the first direction, and an interconnection structure located between the first connection structure and the second connection structure in the first direction; and the interconnection structure is connected with both the first connection structure and the second connection structure; and

Operation S20: arranging the plurality of first semiconductor chips as being stacked along the first direction, and forming a first hybrid bonding layer comprising at least one first bonding structure between two adjacent ones of the first semiconductor chips, to couple the conductive structures in the two adjacent ones of the first semiconductor chips through the first bonding structure.

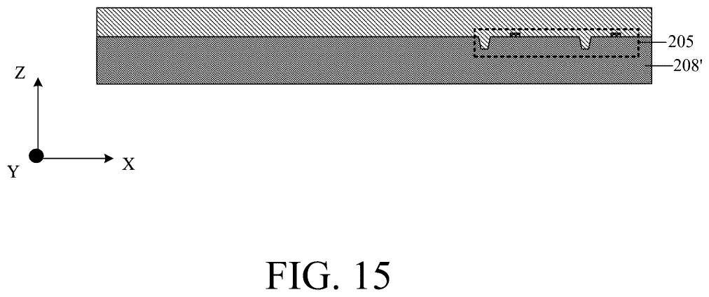

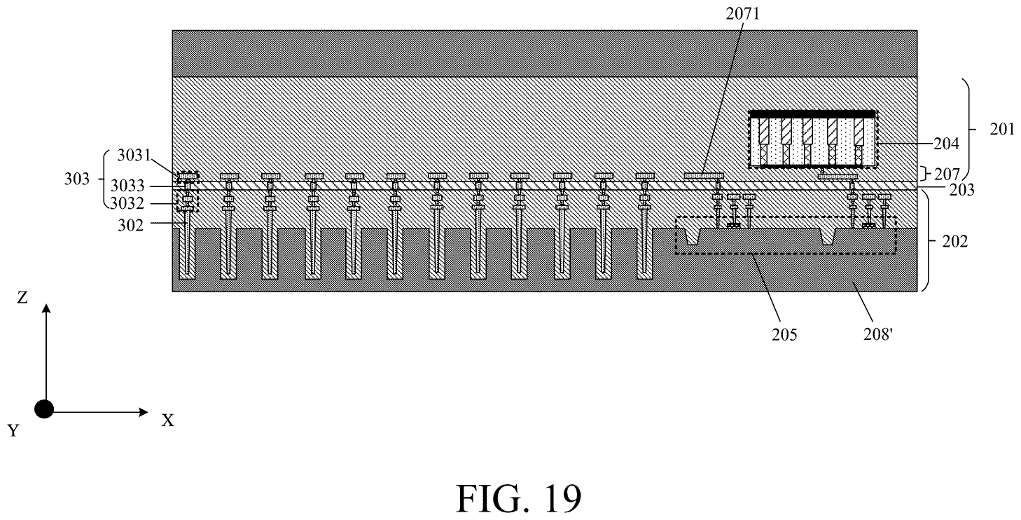

FIGS. 15 to 24 are schematic structural diagrams of a fabrication process of a semiconductor package structure provided by examples of the present disclosure. In the following, the fabrication method of a semiconductor package structure provided by the examples of the present disclosure will be described in conjunction with FIGS. 14 to 24.

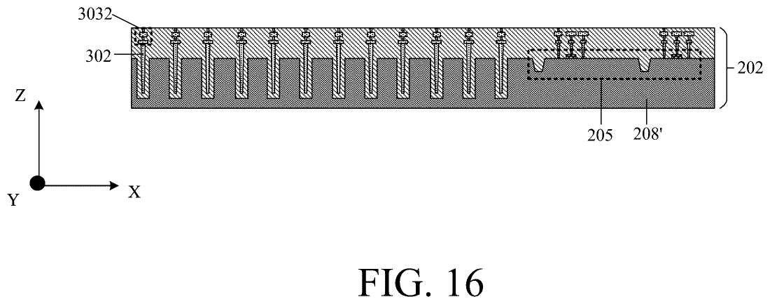

In some examples, with combined reference to FIGS. 15 and 16, forming the first semiconductor chip comprises: forming a second semiconductor structure 202. In an implementation, forming the second semiconductor structure 202 comprises: as shown in FIG. 15, forming a peripheral circuit 205 in an initial semiconductor layer 208′; and as shown in FIG. 16, forming the second connection structure 302 and a second interconnection sub-structure 3032 connected with the second connection structure 302, wherein the second connection structure 302 extends into the initial semiconductor layer 208′ along the first direction and is spaced apart from the initial semiconductor layer 208′ by an isolation layer. Before or simultaneously with the formation of the second connection structure 302 and the second interconnection sub-structure 3032, an interconnection structure leading out a gate, a source, and a drain of a CMOS transistor in the peripheral circuit 205 may also be formed.

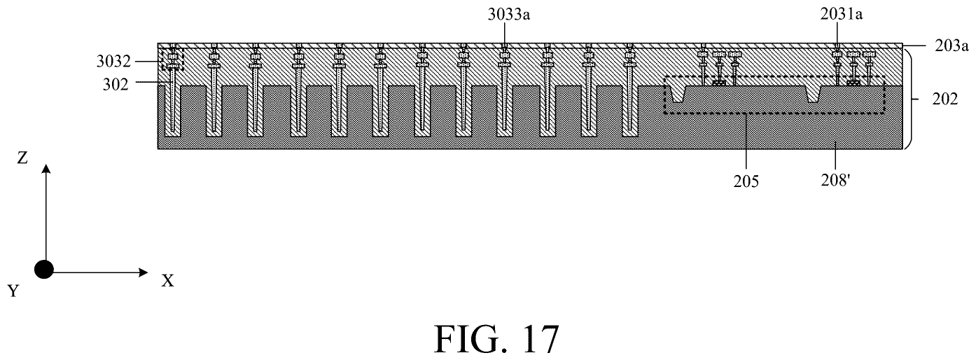

In some examples, with reference to FIG. 17, forming the first semiconductor chip comprises: forming a second bonding sub-layer 203a on a side in two opposite sides of the second semiconductor structure 202 along the first direction, wherein the second bonding sub-layer 203a may comprise a plurality of bonding pads, such as a third bonding pad 2031a coupled with the peripheral circuit 205 and a fourth bonding pad 3033a coupled with the second connection structure 302.

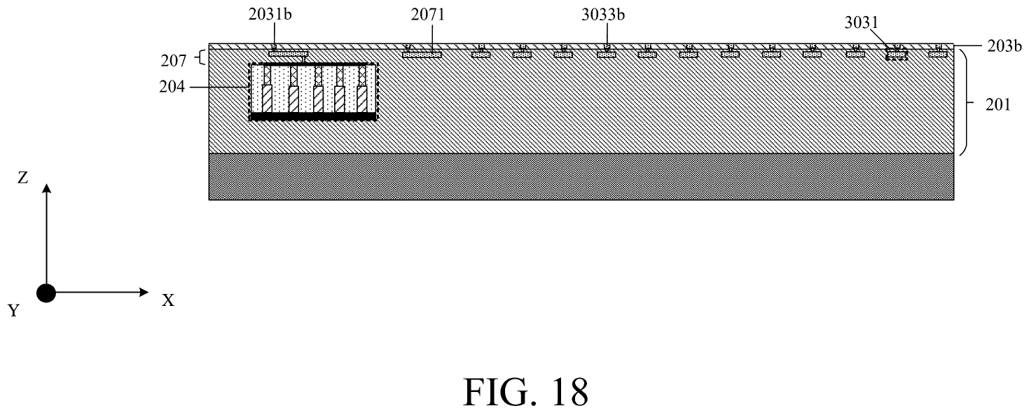

In some examples, with reference to FIG. 18, forming the first semiconductor chip comprises: forming a first semiconductor structure 201 on a substrate comprising forming a memory array 204 and a first routing layer 207, wherein the first routing layer 207 may comprise a first interconnection sub-structure 3031 and first routing 2071; forming a first bonding sub-layer 203b on a side in two opposite sides of the first semiconductor structure 201 along the first direction; wherein the first bonding sub-layer 203b may comprise a plurality of bonding pads, such as a fifth bonding pad 2031b coupled with the memory array 204 and a sixth bonding pad 3033b connected with the first interconnection sub-structure 3031.

In some examples, with combined reference to FIGS. 8, 9, and 18, forming the memory array 204 comprises: forming a plurality of memory cells 210, wherein the memory cell 210 comprises a capacitor structure 211 and a transistor structure 212 arranged as being stacked along the first direction; the capacitor structure comprises a first plate 2111, a second plate 2112, and a dielectric layer 2113 located between the first plate 2111 and the second plate 2112; the transistor structure 212 comprises a semiconductor body 213, a gate structure 214, and a gate dielectric layer 215; the semiconductor body 213 extends along the first direction, and an end in two opposite ends of the semiconductor body 213 along the first direction is connected with the first plate 2111 of the capacitor structure 211; the semiconductor body 213 comprises a first electrode structure 2131, a channel structure 2133, and a second electrode structure 2132 arranged sequentially along the first direction; the gate structure 214 is located on at least one side of the channel structure 2133 along a direction perpendicular to the first direction, and the gate dielectric layer 215 is located between the gate structure 214 and the channel structure 2133.

In some examples, with combined reference to FIGS. 17, 18, and 19, forming the first semiconductor chip comprises: bonding the first bonding sub-layer 203b and the second bonding sub-layer 203a to form a bonding layer 203 between the first semiconductor structure 201 and the second semiconductor structure 202, wherein the bonding layer 203 comprises a second bonding structure 3033 and a third bonding structure 2031, the second bonding structure 3033 is formed by bonding the fourth bonding pad 3033a and the sixth bonding pad 3033b, and the third bonding structure 2031 is formed by bonding the third bonding pad 2031a and the fifth bonding pad 2031b; the memory array 204 is coupled with the peripheral circuit 205 through the third bonding structure 2031; the first interconnection sub-structure 3031 is coupled with the second interconnection sub-structure 3032 through the second bonding structure 3033; and the first interconnection sub-structure 3031, the second interconnection sub-structure 3032, and the second bonding structure 3033 constitute the interconnection structure 303.

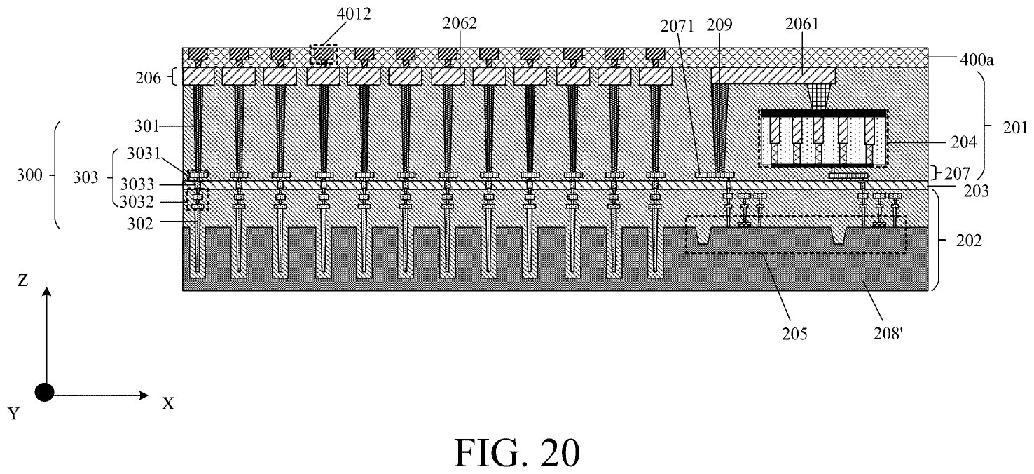

In some examples, with reference to FIG. 20, forming the first semiconductor chip comprises: removing the substrate, and forming the first connection structure 301 in the first semiconductor structure 201, wherein the first connection structure 301 is connected with the first interconnection sub-structure 3031, and the first connection structure 301, the interconnection structure 303, and the second connection structure 302 constitute a conductive structure 300.

In the examples of the present disclosure, the first connection structure 301 and the second connection structure 302 in the conductive structure 300 may be formed separately. In an implementation, the second connection structure 302 may be formed while forming the second semiconductor structure 202, and the first connection structure 301 may be formed after the bonding layer 203 is formed. It may be understood that formation processes of the first connection structure 301 and the second connection structure 302 both may comprise etching an insulation material to form a via extending along the first direction and filling the via with a conductive material, and forming the first connection structure 301 and the second connection structure 302 separately may reduce the depth of the via formed in a single etching process, thereby allowing better control on a difference between a top size and a bottom size of the via, reducing the difficulty of the process while improving the reliability of the formed connection structure.

In some examples, with continued reference to FIG. 20, forming the first semiconductor chip comprises: forming a third connection structure 209 extending along the first direction, while forming the first connection structure 301; and forming a first pad-out layer 206 on a side in two opposite sides of the first connection structure 301 along the first direction away from the second connection structure 302 and on a side in two opposite sides of the memory array 204 along the first direction away from the peripheral circuit 205, wherein the first pad-out layer 206 comprises a first interconnection line 2061 and first leading-out pads 2062; an end in two opposite ends of one of the first leading-out pads 2062 along the first direction is connected with one first connection structure 301; the first interconnection line 2061 is coupled with both the memory array 204 and the peripheral circuit 205; and two opposite ends of the third connection structure 209 along the first direction are connected with the first routing 2071 and the first interconnection line 2061, respectively.

In the examples of the present disclosure, a formation process of the first connection structure 301 may be integrated with a formation process of the third connection structure 209, thereby reducing process operations and saving production costs.

In some examples, with combined reference to FIGS. 8, 9, and 20, after the first pad-out layer 206 is formed, the second plate 2112 of the capacitor structure 211 is coupled with the first interconnection line 2061.

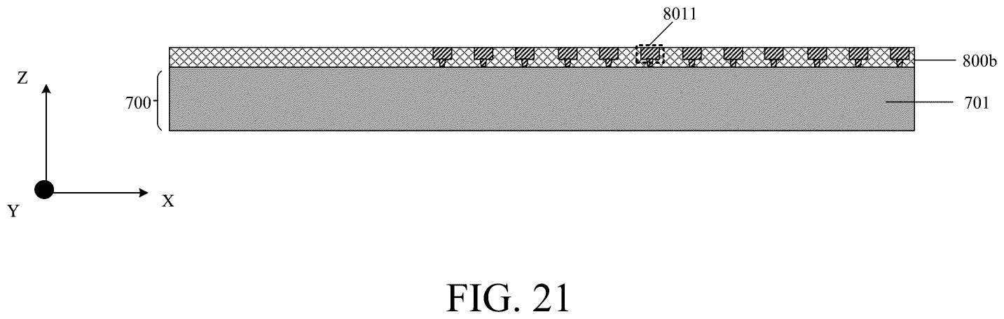

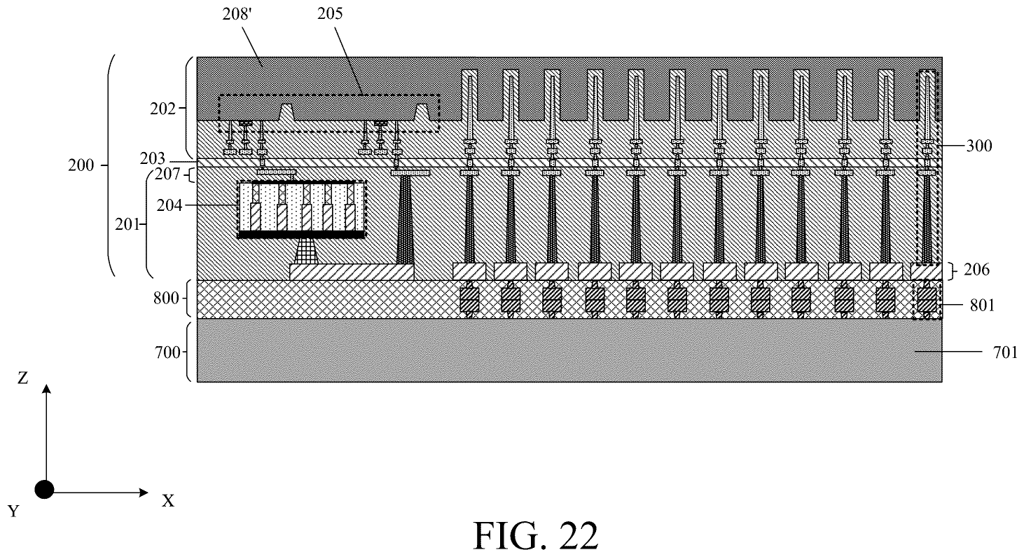

In some examples, with combined reference to FIGS. 20, 21, and 22, the fabrication method of a semiconductor package structure comprises: forming a third semiconductor chip 700 comprising a control circuit 701; and forming a third hybrid bonding layer 800 between the third semiconductor chip 700 and the first semiconductor chip 200, wherein the third hybrid bonding layer 800 comprises a fifth bonding structure 801, and the fifth bonding structure 801 is coupled with the conductive structure 300 and the control circuit 701. In an implementation, as shown in FIG. 20, a fourth bonding sub-layer 400a is formed on a side of the first pad-out layer 206, wherein the fourth bonding sub-layer 400a comprises a second bonding pad 4012; as shown in FIG. 21, a fifth bonding sub-layer 800b is formed on a side of the third semiconductor chip 700, wherein the fifth bonding sub-layer 800b comprises a seventh bonding pad 8011; and as shown in FIG. 22, the fourth bonding sub-layer 400a and the fifth bonding sub-layer 800b are bonded to form the third hybrid bonding layer 800 between the third semiconductor chip 700 and the first semiconductor chip 200, wherein the second bonding pad 4012 and the seventh bonding pad 8011 are bonded to form the fifth bonding structure 801.

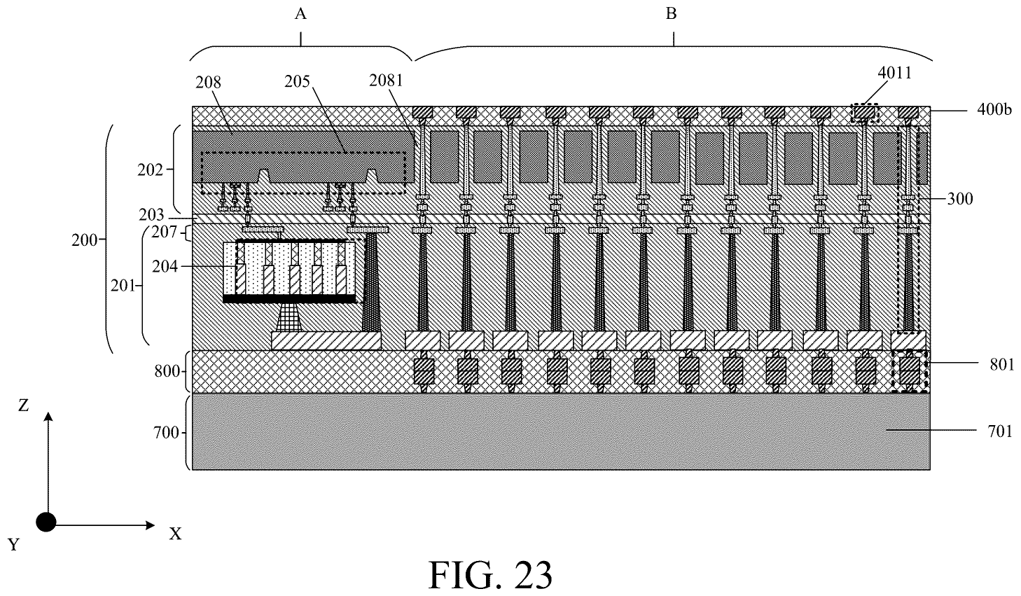

In some examples, with combined reference to FIGS. 22 and 23, the fabrication method of a semiconductor package structure further comprises: removing a portion of the initial semiconductor layer 208′ from a side in two opposite sides of the initial semiconductor layer 208′ along the first direction away from the first semiconductor structure 201, to expose the second connection structure 302, wherein the remaining initial semiconductor layer constitutes a semiconductor layer 208.

In some examples, a portion of the initial semiconductor layer may be removed first by a polishing process, and then a portion of the initial semiconductor layer may further be removed by a wet etching process to form the semiconductor layer 208, such that the bottom of the second connection structure 302 surrounded by the isolation layer protrudes relative to the semiconductor layer 208. Subsequently, the isolation layer covering the semiconductor layer 208 is formed by a deposition process to make top surfaces flush, and then the bottom of the second connection structure 302 is exposed from the isolation layer 2081 by a Chemical Mechanical Polishing (CMP) process. The isolation layer surrounding the second connection structure 302 and the isolation layer covering the semiconductor layer 208 may comprise the same material, and jointly constitute an isolation layer 2081 spacing apart the second connection structure 302 from the semiconductor layer 208.

In the examples of the present disclosure, the deposition process comprises, but is not limited to, Chemical Vapor Deposition (CVD), Low Pressure Chemical Vapor Deposition (LPCVD), Plasma Enhanced Chemical Vapor Deposition (PECVD), Physical Vapor Deposition (PVD), and Atomic Layer Deposition (ALD). The etching process comprises, but is not limited to, Plasma Etching (PE), Sputtering Etching (SE), Ion Beam Etching (IBE), and Reactive Ion Etching (RIE).

In some examples, with combined reference to FIGS. 23 and 7, the first semiconductor chip 200 comprises a memory region A and a contact region B arranged in juxtaposition along a direction perpendicular to the first direction, wherein at least one conductive structure 300 is located in the contact region B, and the memory array 204 and the peripheral circuit 205 are located in the memory region A.

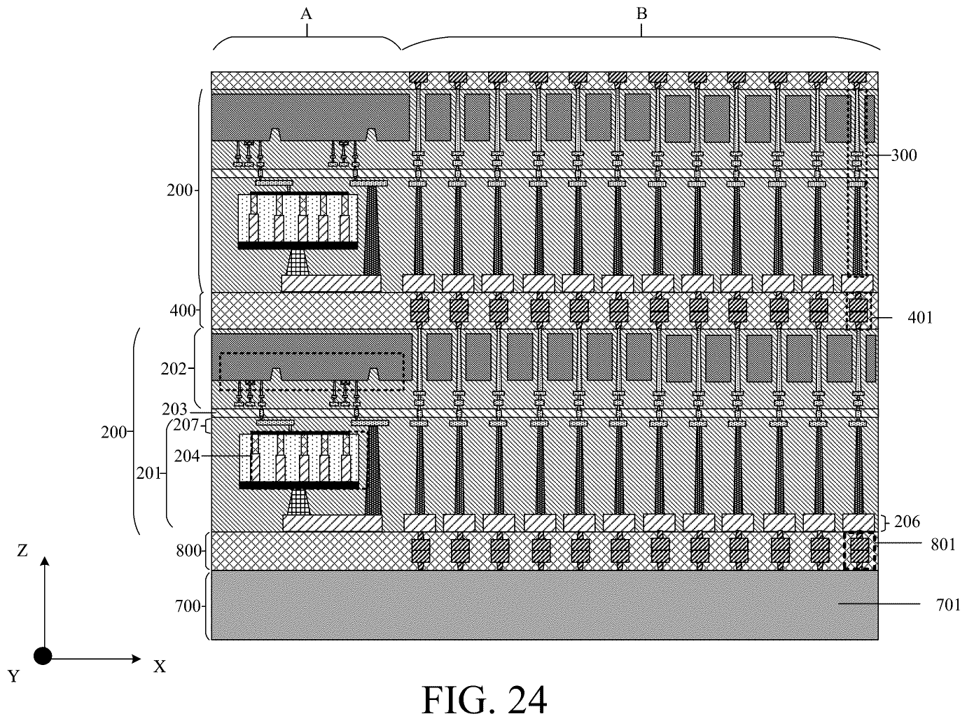

In some examples, with combined reference to FIGS. 23 and 24, the fabrication method of a semiconductor package structure further comprises: forming a third bonding sub-layer 400b on a side in two opposite sides of the semiconductor layer 208 along the first direction away from the first semiconductor structure 201, wherein the third bonding sub-layer 400b comprises at least one first bonding pad 4011; and bonding the third bonding sub-layer 400b on one first semiconductor chip with the fourth bonding sub-layer 400a on another first semiconductor chip 200, to form the first hybrid bonding layer 400 between two adjacent ones of the first semiconductor chips 200.

In some examples, with combined reference to FIGS. 4 and 24, the third bonding sub-layer 400b may comprise a first dielectric layer 402 and at least one first bonding pad 4011 located in the first dielectric layer 402, and the fourth bonding sub-layer 400a may comprise a second dielectric layer 403 and at least one second bonding pad 4012 located in the second dielectric layer 403. A process of forming the first hybrid bonding layer 400 may comprise: first contacting the third sub-bonding layer 400b with the fourth sub-bonding layer 400a. In an implementation, the first bonding pad 4011 is contacted with the second bonding pad 4012 one to one, and the first dielectric layer 402 is contacted with the second dielectric layer 403; then metal-to-metal bonding may be formed between the first bonding pad 4011 and the second bonding pad 4012 by thermal treatment, and dielectric material-dielectric material bonding may be formed between the first dielectric layer 402 and the second dielectric layer 403. After the hybrid bonding is completed, there may be no distinct boundary between the first bonding pad 4011 and the second bonding pad 4012, and there may be no distinct boundary between the first dielectric layer 402 and the second dielectric layer 403.

In some examples, with combined reference to FIGS. 24 and 11, through a bonding pattern the same as that in the above examples, the plurality of first semiconductor chips 200 arranged as being stacked along the first direction and the first hybrid bonding layer 400 located between two adjacent ones of the first semiconductor chips 200 in the first direction may be formed over the third semiconductor chip 700. Furthermore, the fabrication method of a semiconductor package structure further comprises: forming a second semiconductor chip 500, wherein the second semiconductor chip 500 comprises a third semiconductor structure 501 and a fourth semiconductor structure 502 arranged as being stacked along the first direction; the third semiconductor structure 501 comprises a third pad-out layer 503 on a side in two opposite sides along the first direction away from the fourth semiconductor structure 502; and the third pad-out layer 503 comprises at least one third leading-out pad 5031; and stacking the second semiconductor chip 500 over the plurality of first semiconductor chips 200, and forming a second hybrid bonding layer 600 between the first semiconductor chip 200 closest to the second semiconductor chip 500 and the second semiconductor chip 500, wherein the third semiconductor structure 501 is located between the fourth semiconductor structure 502 and the first semiconductor chip 200; the second hybrid bonding layer 600 comprises at least one fourth bonding structure 601; and the fourth bonding structure 601 is coupled with the third leading-out pad 5031 and the conductive structure 300.

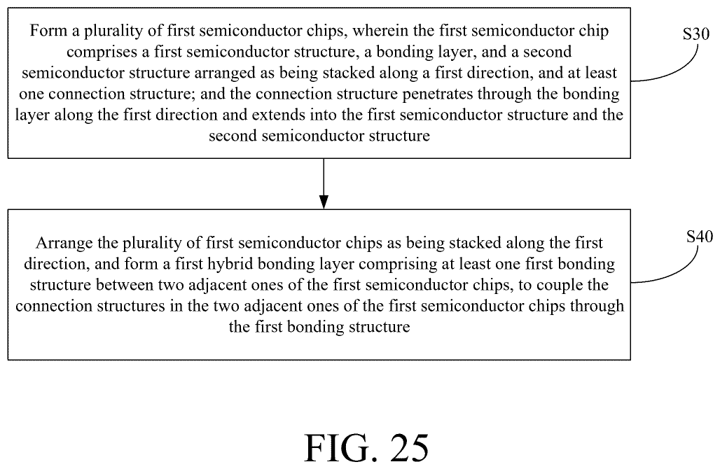

Based on an idea similar to that of the semiconductor package structure mentioned above, the present disclosure further provides a fabrication method of a semiconductor package structure. FIG. 25 is a schematic flow diagram of a fabrication method of a semiconductor package structure provided by examples of the present disclosure. The fabrication method of a semiconductor package structure comprises the following operations:

Operation S30: forming a plurality of first semiconductor chips, wherein the first semiconductor chip comprises a first semiconductor structure, a bonding layer, and a second semiconductor structure arranged as being stacked along a first direction, and at least one connection structure; and the connection structure penetrates through the bonding layer along the first direction and extends into the first semiconductor structure and the second semiconductor structure; and

Operation S40: arranging the plurality of first semiconductor chips as being stacked along the first direction, and forming a first hybrid bonding layer comprising at least one first bonding structure between two adjacent ones of the first semiconductor chips, to couple the connection structures in the two adjacent ones of the first semiconductor chips through the first bonding structure.

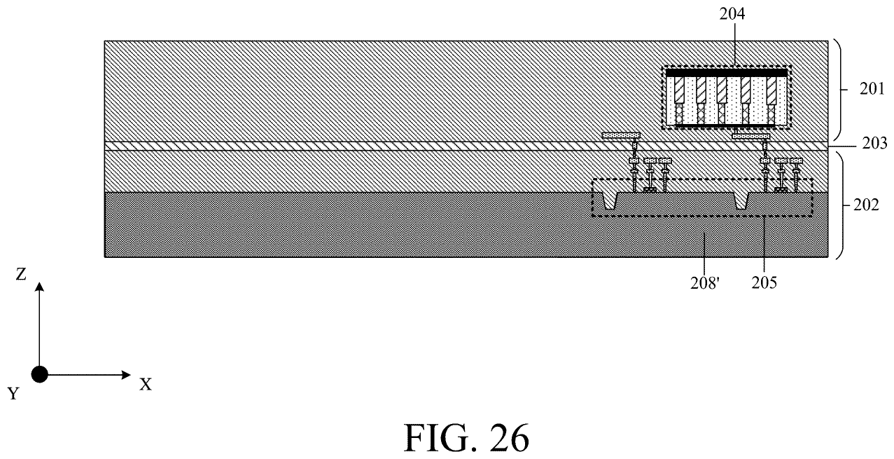

FIGS. 26 to 29 are schematic structural diagrams of a fabrication process of a semiconductor package structure provided by examples of the present disclosure. In the following, the fabrication method of a semiconductor package structure provided by the examples of the present disclosure will be described in conjunction with FIGS. 25 to 29. It is to be noted that a fabrication process of the semiconductor package structure here is similar to the fabrication process of the semiconductor package structure corresponding to FIGS. 14 to 24. Therefore, the illustration is focused on differences between the fabrication method of the semiconductor package structure here and the fabrication method of the semiconductor package structure provided by the above examples.

In some examples, with reference to FIG. 26, forming the first semiconductor chip 200 comprises: forming the first semiconductor structure 201 comprising the memory array 204, forming the second semiconductor structure 202 comprising the peripheral circuit 205, and forming the bonding layer 203 between the first semiconductor structure 201 and the second semiconductor structure 202.

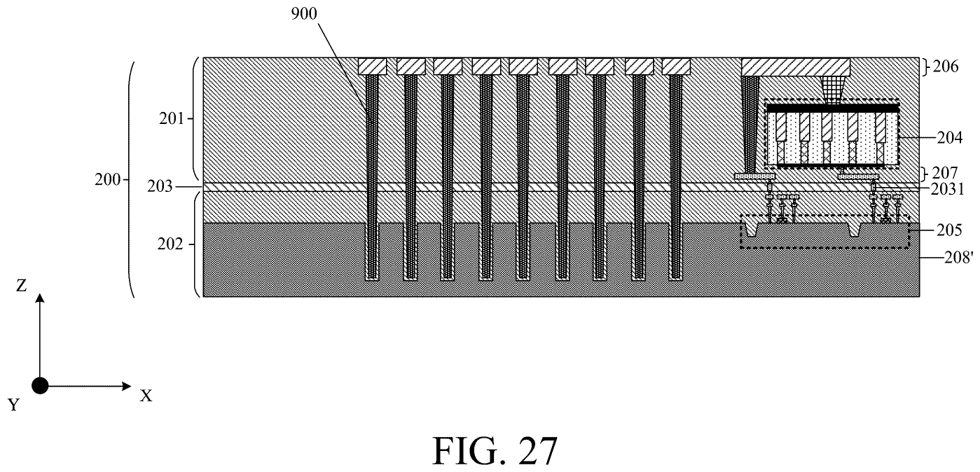

In some examples, with reference to FIG. 27, forming the first semiconductor chip 200 further comprises: forming at least one connection structure 900 extending along the first direction, wherein the connection structure 900 penetrates through the bonding layer 203 and extends into the initial semiconductor layer 208′; and forming the first pad-out layer 206 on a side of the connection structure 900.

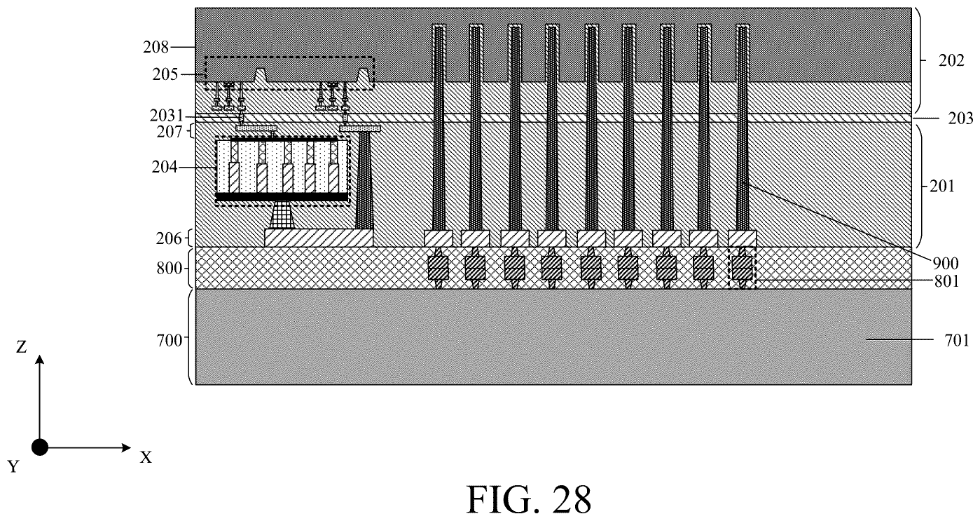

In some examples, with reference to FIG. 28, the fabrication method of a semiconductor package structure comprises: forming the third hybrid bonding layer 800 between the first semiconductor chip 200 and the third semiconductor chip 700.

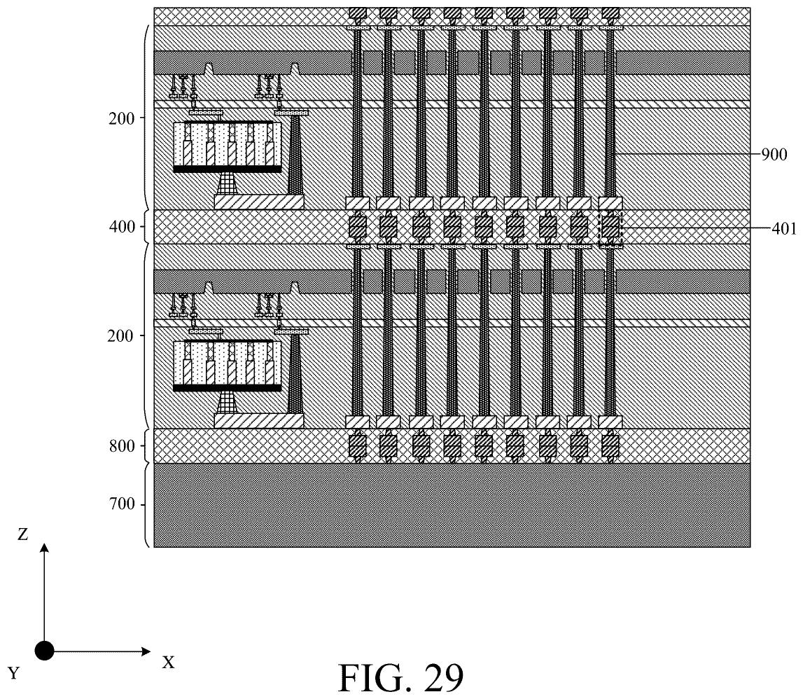

In some examples, with reference to FIG. 29, the fabrication method of a semiconductor package structure comprises: removing a portion of the initial semiconductor layer 208′ to expose the connection structure 900; stacking another first semiconductor chip 200 on the first semiconductor chip 200, and forming the first hybrid bonding layer 400 between two adjacent ones of the first semiconductor chips 200.

In some examples, with combined reference to FIGS. 12 and 29, the fabrication method of a semiconductor package structure further comprises: forming the second semiconductor chip 500, and forming the second hybrid bonding layer 600 between the second semiconductor chip 500 and the topmost first semiconductor chip 200.

In the examples of the present disclosure, after the bonding layer 203 is formed between the first semiconductor structure 201 and the second semiconductor structure 202, the connection structure 900 may be formed by a single etching process and a conductive material filling process, thereby reducing process operations and reducing a contact resistance between different metal materials.

The features disclosed in several device examples provided by the present disclosure may be combined freely to obtain a new device example in the case of no conflicts.

The methods disclosed in several method examples provided by the present disclosure may be combined freely to obtain a new method example in case of no conflicts.

Examples of the present disclosure provide a semiconductor package structure and a fabrication method thereof.

In a first aspect, the examples of the present disclosure provide a semiconductor package structure, comprising:
a plurality of first semiconductor chips arranged as being stacked along a first direction, wherein the first semiconductor chip comprises at least one conductive structure, the conductive structure comprises a first connection structure extending along the first direction, a second connection structure extending along the first direction, and an interconnection structure located between the first connection structure and the second connection structure in the first direction; and the interconnection structure is connected with both the first connection structure and the second connection structure; and a first hybrid bonding layer located between two adjacent ones of the first semiconductor chips in the first direction, wherein the first hybrid bonding layer comprises at least one first bonding structure; and the first bonding structure is coupled with the conductive structures in the two adjacent ones of the first semiconductor chips.

In a second aspect, the examples of the present disclosure provide a semiconductor package structure, comprising: a plurality of first semiconductor chips arranged as being stacked along a first direction and a first hybrid bonding layer located between two adjacent ones of the first semiconductor chips in the first direction, wherein the first semiconductor chip comprises a first semiconductor structure, a bonding layer, and a second semiconductor structure arranged as being stacked along the first direction, and at least one connection structure; the connection structure penetrates through the bonding layer along the first direction and extends into the first semiconductor structure and the second semiconductor structure; and the first hybrid bonding layer comprises at least one first bonding structure; and the first bonding structure is coupled with the connection structures in the two adjacent ones of the first semiconductor chips.

In a third aspect, the examples of the present disclosure provide a fabrication method of a semiconductor package structure, comprising: forming a plurality of first semiconductor chips, wherein the first semiconductor chip comprises at least one conductive structure; the conductive structure comprises a first connection structure extending along a first direction, a second connection structure extending along the first direction, and an interconnection structure located between the first connection structure and the second connection structure in the first direction; and the interconnection structure is connected with both the first connection structure and the second connection structure; and arranging the plurality of first semiconductor chips as being stacked along the first direction, and forming a first hybrid bonding layer comprising at least one first bonding structure between two adjacent ones of the first semiconductor chips, to couple the conductive structures in the two adjacent ones of the first semiconductor chips through the first bonding structure.

In a fourth aspect, the examples of the present disclosure provide a fabrication method of a semiconductor package structure, comprising: forming a plurality of semiconductor chips, wherein the first semiconductor chip comprises a first semiconductor structure, a bonding layer, and a second semiconductor structure arranged as being stacked along a first direction, and at least one connection structure; and the connection structure penetrates through the bonding layer along the first direction and extends into the first semiconductor structure and the second semiconductor structure; and arranging the plurality of first semiconductor chips as being stacked along the first direction, and forming a first hybrid bonding layer comprising at least one first bonding structure between two adjacent ones of the first semiconductor chips, to couple the connection structures in the two adjacent ones of the first semiconductor chips through the first bonding structure.

In the technical solutions provided by the present disclosure, the plurality of first semiconductor chips are arranged as being stacked along the first direction, the first semiconductor chip comprises the conductive structure or the connection structure extending along the first direction, two adjacent ones of the first semiconductor chips are connected through the first hybrid bonding layer, and the first hybrid bonding layer comprises the first bonding structure coupled with the conductive structure or the connection structure. There may be a smaller spacing between first bonding structures, and since no space is required to be reserved for a bottom filling material, there may also be a smaller spacing between two adjacent ones of the first semiconductor chips. On the one hand, more first bonding structures may be disposed in the same area, thereby facilitating high broadband connection between the chips. On the other hand, the thickness of the semiconductor package structure may be reduced, facilitating the miniaturization of the semiconductor package structure.

The above descriptions are merely implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A semiconductor package structure, comprising:
a plurality of first semiconductor chips arranged as being stacked along a first direction, wherein the plurality of first semiconductor chips each comprise at least one conductive structure; the conductive structure comprises a first connection structure extending along the first direction, a second connection structure extending along the first direction, and an interconnection structure located between the first connection structure and the second connection structure in the first direction; and the interconnection structure is connected with both the first connection structure and the second connection structure; and
a first hybrid bonding layer located between two adjacent ones of the plurality of first semiconductor chips in the first direction, wherein the first hybrid bonding layer comprises at least one first bonding structure; and the first bonding structure is coupled with the conductive structures in the two adjacent ones of the plurality of first semiconductor chips.

2. The semiconductor package structure of claim 1, wherein the first hybrid bonding layer comprises:
a first dielectric layer and a second dielectric layer arranged as being stacked along the first direction; the first bonding structure comprises a first bonding pad and a second bonding pad arranged as being stacked along the first direction; the first bonding pad is located in the first dielectric layer, and the second bonding pad is located in the second dielectric layer; the first bonding pad is in contact with the second bonding pad, and the first dielectric layer is in contact with the second dielectric layer.

3. The semiconductor package structure of claim 1, wherein the interconnection structure comprises a first interconnection sub-structure, a second bonding structure, and a second interconnection sub-structure arranged as being stacked along the first direction, the first interconnection sub-structure is located between the first connection structure and the second bonding structure, and the second interconnection sub-structure is located between the second connection structure and the second bonding structure.

4. The semiconductor package structure of claim 3, wherein the first semiconductor chip comprises:
a first semiconductor structure, a bonding layer, and a second semiconductor structure arranged as being stacked along the first direction; the first semiconductor structure comprises the first connection structure, the first interconnection sub-structure, and a memory array; the second semiconductor structure comprises the second connection structure, the second interconnection sub-structure, and a peripheral circuit; the bonding layer comprises the second bonding structure and a third bonding structure; and the memory array is coupled with the peripheral circuit through the third bonding structure.

5. The semiconductor package structure of claim 4, wherein the first semiconductor chip comprises a memory region and a contact region arranged in juxtaposition along a direction perpendicular to the first direction, the at least one conductive structure is located in the contact region, and the memory array and the peripheral circuit are located in the memory region, wherein the second semiconductor structure comprises:
a semiconductor layer extending along the direction perpendicular to the first direction; a partial structure of the peripheral circuit is located in the semiconductor layer in the memory region; and the second connection structure penetrates through the semiconductor layer located in the contact region along the first direction.

6. The semiconductor package structure of claim 4, wherein the first semiconductor structure further comprises:
a first pad-out layer located on a side in two opposite sides of the memory array along the first direction away from the peripheral circuit and located on a side in two opposite sides of the first connection structure along the first direction away from the second connection structure; the first pad-out layer comprises a first interconnection line and first leading-out pads; two opposite ends of one of the first leading-out pads along the first direction are connected with one first connection structure and one first bonding structure, respectively; and the first interconnection line is coupled with both the memory array and the peripheral circuit.

7. The semiconductor package structure of claim 6, wherein in a second direction, a size of an end in two opposite ends of the first connection structure along the first direction close to the second connection structure is less than a size of an end away from the second connection structure; in the second direction, a size of an end in two opposite ends of the second connection structure along the first direction close to the first connection structure is greater than a size of an end away from the first connection structure; and the second direction is perpendicular to the first direction.

8. The semiconductor package structure of claim 6, wherein the memory array comprises:
a plurality of memory cells; the memory cell comprises a capacitor structure and a transistor structure arranged as being stacked along the first direction; the capacitor structure comprises a first plate, a second plate, and a dielectric layer located between the first plate and the second plate; the transistor structure comprises a semiconductor body extending along the first direction; an end in two opposite ends of the semiconductor body along the first direction is connected with the first plate of the capacitor structure; and the second plate of the capacitor structure is coupled with the first interconnection line, wherein the semiconductor body comprises a first electrode structure, a channel structure, and a second electrode structure arranged sequentially along the first direction; and
the transistor structure further comprises a gate structure located on at least one side of the channel structure along a direction perpendicular to the first direction, wherein the gate structures of a plurality of transistor structures arranged along a third direction are connected to constitute a word line structure extending along the third direction; and the third direction is perpendicular to the first direction.

9. The semiconductor package structure of claim 1, further comprising:
a second semiconductor chip arranged as being stacked with the plurality of first semiconductor chips along the first direction, wherein the second semiconductor chip comprises a third semiconductor structure and a fourth semiconductor structure arranged as being stacked along the first direction; the third semiconductor structure is located between the fourth semiconductor structure and the first semiconductor chip; the third semiconductor structure comprises a third pad-out layer on a side in two opposite sides along the first direction away from the fourth semiconductor structure; and the third pad-out layer comprises at least one third leading-out pad; and
a second hybrid bonding layer located between the first semiconductor chip closest to the second semiconductor chip and the second semiconductor chip, wherein the second hybrid bonding layer comprises at least one fourth bonding structure; and the fourth bonding structure is coupled with the third leading-out pad and coupled with the conductive structure of the first semiconductor chip closest to the second semiconductor chip.

10. A semiconductor package structure, comprising:
a plurality of first semiconductor chips arranged as being stacked along a first direction and a first hybrid bonding layer located between two adjacent ones of the plurality of first semiconductor chips in the first direction,
wherein the first semiconductor chip comprises a first semiconductor structure, a bonding layer, and a second semiconductor structure arranged as being stacked along the first direction, and at least one connection structure; the connection structure penetrates through the bonding layer along the first direction and extends into the first semiconductor structure and the second semiconductor structure; and
wherein the first hybrid bonding layer comprises at least one first bonding structure; and the first bonding structure is coupled with the connection structures in the two adjacent ones of the plurality of first semiconductor chips.

11. The semiconductor package structure of claim 10, wherein the first hybrid bonding layer comprises:
a first dielectric layer and a second dielectric layer arranged as being stacked along the first direction; the first bonding structure comprises a first bonding pad and a second bonding pad arranged as being stacked along the first direction; the first bonding pad is located in the first dielectric layer, and the second bonding pad is located in the second dielectric layer; the first bonding pad is in contact with the second bonding pad, and the first dielectric layer is in contact with the second dielectric layer.

12. The semiconductor package structure of claim 10, wherein the first semiconductor structure further comprises:
a first pad-out layer located on a side in two opposite sides of a memory array along the first direction away from a peripheral circuit and extending into a contact region along the direction perpendicular to the first direction; the first pad-out layer comprises a first interconnection line and first leading-out pads; two opposite ends of one of the first leading-out pads along the first direction are connected with one connection structure and one first bonding structure, respectively; and the first interconnection line is coupled with both the memory array and the peripheral circuit.

13. The semiconductor package structure of claim 12, wherein the memory array comprises:
a plurality of memory cells; the memory cell comprises a capacitor structure and a transistor structure arranged as being stacked along the first direction; the capacitor structure comprises a first plate, a second plate, and a dielectric layer located between the first plate and the second plate; the transistor structure comprises a semiconductor body extending along the first direction; an end in two opposite ends of the semiconductor body along the first direction is connected with the first plate of the capacitor structure; and the second plate of the capacitor structure is coupled with the first interconnection line, wherein the semiconductor body comprises: a first electrode structure, a channel structure, and a second electrode structure arranged sequentially along the first direction;
the transistor structure further comprises a gate structure located on at least one side of the channel structure along a direction perpendicular to the first direction, wherein the gate structures of a plurality of transistor structures arranged along a third direction are connected to constitute a word line structure extending along the third direction; and the third direction is perpendicular to the first direction.

14. The semiconductor package structure of claim 10, further comprising:
a second semiconductor chip arranged as being stacked with the plurality of first semiconductor chips along the first direction, wherein the second semiconductor chip comprises a third semiconductor structure and a fourth semiconductor structure arranged as being stacked along the first direction; the third semiconductor structure is located between the fourth semiconductor structure and the first semiconductor chip; the third semiconductor structure comprises a third pad-out layer on a side in two opposite sides along the first direction away from the fourth semiconductor structure; and the third pad-out layer comprises at least one third leading-out pad; and
a second hybrid bonding layer located between the first semiconductor chip closest to the second semiconductor chip and the second semiconductor chip, wherein the second hybrid bonding layer comprises at least one fourth bonding structure; and the fourth bonding structure is coupled with the third leading-out pad and coupled with the connection structure of the first semiconductor chip closest to the second semiconductor chip.

15. A fabrication method of a semiconductor package structure, the fabrication method comprising:
forming a plurality of first semiconductor chips, wherein the first semiconductor chip comprises at least one conductive structure; the conductive structure comprises a first connection structure extending along a first direction, a second connection structure extending along the first direction, and an interconnection structure located between the first connection structure and the second connection structure in the first direction; and the interconnection structure is connected with both the first connection structure and the second connection structure; and
arranging the plurality of first semiconductor chips as being stacked along the first direction, and forming a first hybrid bonding layer comprising at least one first bonding structure between two adjacent ones of the first semiconductor chips, to couple the conductive structures in the two adjacent ones of the first semiconductor chips through the first bonding structure.

16. The fabrication method of a semiconductor package structure of claim 15, wherein forming the first semiconductor chips comprises:
forming a first semiconductor structure comprising forming a memory array and a first interconnection sub-structure;
forming a first bonding sub-layer on a side in two opposite sides of the first semiconductor structure along the first direction;
forming a second semiconductor structure comprising forming a peripheral circuit, the second connection structure, and a second interconnection sub-structure connected with the second connection structure;
forming a second bonding sub-layer on a side in two opposite sides of the second semiconductor structure along the first direction;
bonding the first bonding sub-layer and the second bonding sub-layer to form a bonding layer between the first semiconductor structure and the second semiconductor structure, wherein the bonding layer comprises a second bonding structure and a third bonding structure; the memory array is coupled with the peripheral circuit through the third bonding structure; the first interconnection sub-structure is coupled with the second interconnection sub-structure through the second bonding structure; and the first interconnection sub-structure, the second interconnection sub-structure, and the second bonding structure constitute the interconnection structure; and
forming the first connection structure in the first semiconductor structure, wherein the first connection structure is connected with the first interconnection sub-structure.

17. The fabrication method of a semiconductor package structure of claim 15, wherein the forming the second semiconductor structure further comprises:
forming an initial semiconductor layer extending along a direction perpendicular to the first direction;
forming a partial structure of a peripheral circuit in the initial semiconductor layer; and
forming the second connection structure extending into the initial semiconductor layer along the first direction;
the forming the first semiconductor chips further comprises:
removing a portion of the initial semiconductor layer from a side in two opposite sides of the initial semiconductor layer along the first direction away from the first semiconductor structure, to expose the second connection structure and form a semiconductor layer.

18. The fabrication method of a semiconductor package structure of claim 17, wherein the forming the first semiconductor chips further comprises:
forming a first pad-out layer on a side in two opposite sides of the first connection structure along the first direction away from the second connection structure and on a side in two opposite sides of a memory array along the first direction away from the peripheral circuit, wherein the first pad-out layer comprises a first interconnection line and first leading-out pads; an end in two opposite ends of one of the first leading-out pads along the first direction is connected with one first connection structure; and the first interconnection line is coupled with both the memory array and the peripheral circuit.

19. The fabrication method of a semiconductor package structure of claim 18, further comprising:
forming a third bonding sub-layer on a side in two opposite sides of the first pad-out layer along the first direction away from the second semiconductor structure, wherein the third bonding sub-layer comprises a first dielectric layer and at least one first bonding pad located in the first dielectric layer;
forming a fourth bonding sub-layer on a side in two opposite sides of the semiconductor layer along the first direction away from the first semiconductor structure, wherein the fourth bonding sub-layer comprises a second dielectric layer and at least one second bonding pad located in the second dielectric layer; and
bonding the third bonding sub-layer on one of the first semiconductor chips with the fourth bonding sub-layer on another of the first semiconductor chips, to form the first hybrid bonding layer between two adjacent ones of the first semiconductor chips, wherein one of the first bonding pads is bonded with one of the second bonding pads, to form one first bonding structure; the first dielectric layer is bonded with the second dielectric layer; and an other end in the two opposite ends of one of the first leading-out pads along the first direction is connected with one first bonding structure.

20. The fabrication method of a semiconductor package structure of claim 18, wherein forming the memory array comprises:
forming a plurality of memory cells, wherein the memory cell comprises a capacitor structure and a transistor structure arranged as being stacked along the first direction; the capacitor structure comprises a first plate, a second plate, and a dielectric layer located between the first plate and the second plate; the transistor structure comprises a semiconductor body extending along the first direction; an end in two opposite ends of the semiconductor body along the first direction is connected with the first plate of the capacitor structure; and the second plate of the capacitor structure is coupled with the first interconnection line.
